(19) United States
(12) Patent Application Publication
(10) Pub. No.: US 2025/0257085 A1
(43) Pub. Date: Aug. 14, 2025

(54) COMPOSITE MATERIAL, ITS PREPARATION AND USE IN ORGANIC SOLAR CELL

(71) Applicant: City University of Hong Kong, Kowloon (HK)

(72) Inventors: Alex Kwan Yue Jen, Kowloon (HK); Baobing Fan, Kowloon (HK)

(21) Appl. No.: 18/944,257

(22) Filed: Nov. 12, 2024

Related U.S. Application Data
(60) Provisional application No. 63/551,220, filed on Feb. 8, 2024.

(51) Int. Cl. C07F 9/54; H10K 50/15; H10K 71/12; H10K 85/50; H10K 85/60

(52) U.S. Cl. CPC C07F 9/5463; H10K 50/156; H10K 71/12; H10K 85/50; H10K 85/6572

(57) ABSTRACT

A composite material for an organic solar cell including a polyoxometalate (POM) cluster and a self-assembled monolayer (SAM) of a carbazole-based compound. The method for preparing the composite material and the use of such a composite material are also addressed.

### TECHNICAL FIELD

The present invention relates to a composite material, for example, particularly, but not exclusively, a composite material having a polyoxometalate (POM) cluster and a self-assembled monolayer (SAM) of a carbazole-based compound for organic solar cells (OSCs). The present invention also relates to the preparation of the composite material and the use of the composite material in OSCs.

### BACKGROUND OF THE INVENTION

It is believed that hole transporting layer (HTL) may play a critical role in determining the efficiency and stability for p-i-n-structure organic photovoltaics (OPV)/organic solar cell (OSCs). Typically, HTL may comprise materials such as polyelectrolyte, metal oxides, p-type self-assembled monolayer (SAM), polyoxometalate (POM), etc. These materials, however, may possess different defects in OPV/OSCs applications.

In particular, polyelectrolyte HTL such as PEDOT:PSS may suffer from phase separation that causes instability. In addition, its relatively low optical bandgap may induce certain parasitic absorption to compromise light harvesting of the active layer. Metal oxides such as MoO₃, WO₃, NiO and the like generally require harsh processing conditions. P-Type SAM may suffer from challenges to form full coverage on the bottom electrode. POM may suffer from low conductivity and deep-lying energy level that would block the hole extraction by the bottom electrode when coated as a thick layer.

The present invention thus seeks to eliminate or at least mitigate such shortcomings by providing a new or otherwise improved HTL material for OPV/OSCs.

### SUMMARY OF THE INVENTION

In a first aspect of the present invention, there is provided a composite material for an organic solar cell comprising a polyoxometalate (POM) cluster and a self-assembled monolayer (SAM) of a carbazole-based compound.

It is optional that the carbazole-based compound has a Formula of:

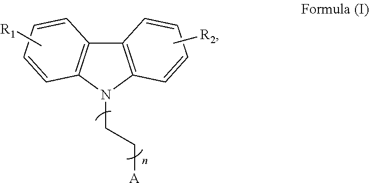

wherein: R₁ and R² each represent a mono- or di-substitutions, and are each independently selected from the group consisting of hydrogen, halogen, alkyl, alkoxy, fused ring, non-fused ring, and a combination thereof; n is a positive integer being 1-3; and A is an anchoring group including an acid moiety.

Optionally, R₁ and R₂ are each independently selected from the group consisting of H, F, Cl, Br, I, C₁-C₆ alkyl, C₁-C₆ alkoxy, C6-C10 aryl, C5-C10 heteroaryl and a combination thereof.

Optionally, A is selected from the group consisting of carboxyl group, sulfo group, mercapto group and phosphono group.

It is optional that R₁ and R₂ are identical.

It is optional that R₁ and R₂ are different.

In an optional embodiment, the carbazole-based compound has a Formula selected from the group consisting of:

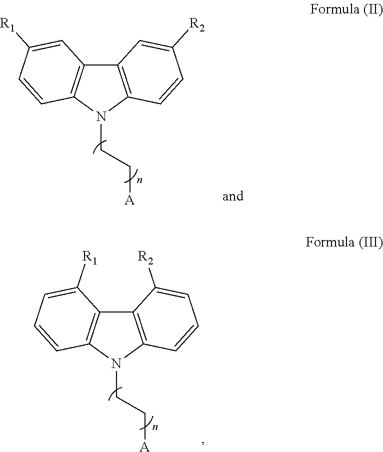

wherein: R₁ and R² each represent a mono-substitution and are selected from the group consisting of H, F, Cl, Br, I, methyl, ethyl, methoxy, ethoxy, tert-butoxy, and phenyl; n is 1-3; and A is selected from the group consisting of carboxyl group, sulfo group, mercapto group, and phosphono group.

In an optional embodiment, the carbazole-based compound has a Formula selected from the group consisting of:

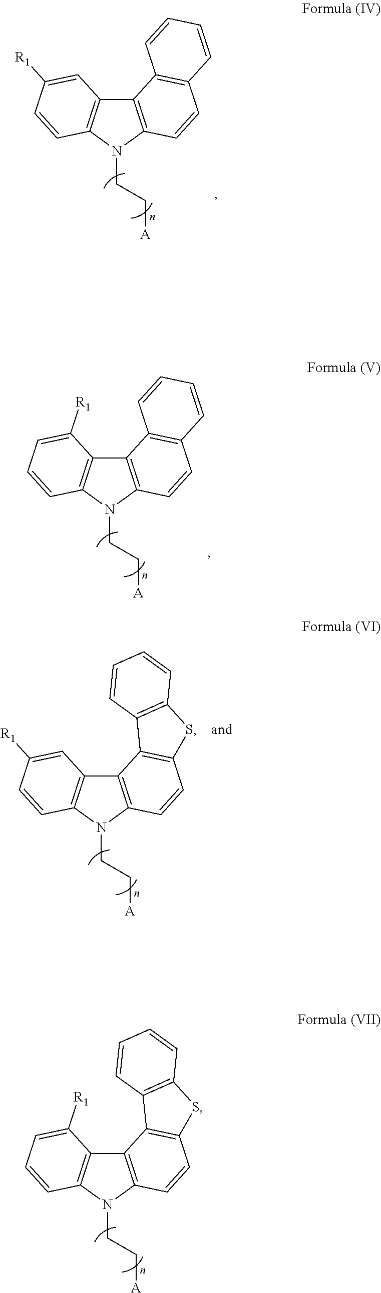

wherein: R₁ represents a mono-substitution and is selected from the group consisting of H, F, Cl, Br, I, methyl, ethyl, methoxy, ethoxy, tert-butoxy, and phenyl; n is 1-3; and A is selected from the group consisting of carboxyl group, sulfo group, mercapto group and phosphono group.

Optionally, the carbazole-based compound has a Formula selected from the group consisting of:

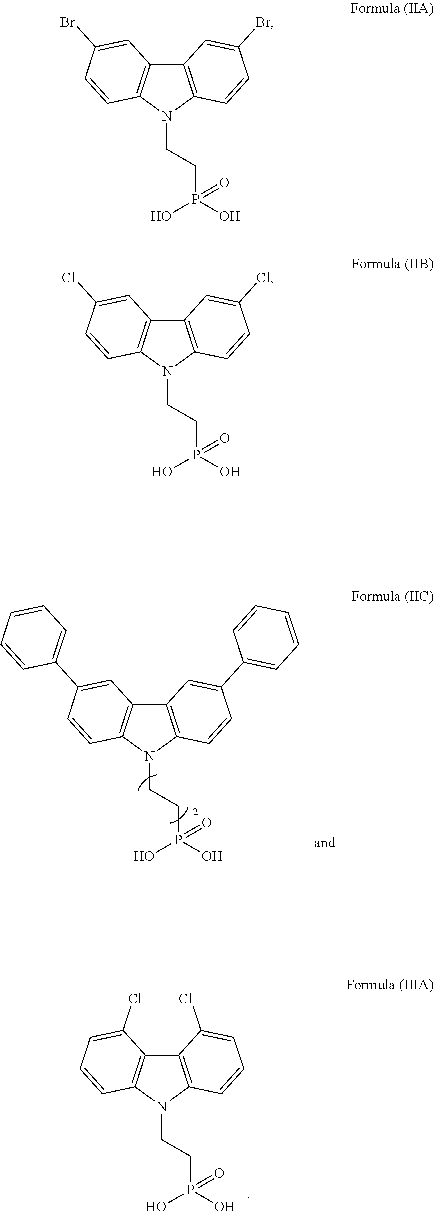

In an optional embodiment, the POM cluster comprises a Keggin structure.

In an optional embodiment, the POM cluster comprises a Dawson structure.

Optionally, the POM cluster has a formula of XₐYMₙM′₁₂₋ₙO₄₀, and wherein X is a cation selected from the group consisting of H⁺, NH₄⁺, NR₄⁺ with R being a C1-C4 linear or branched alkyl; a is 3 or 4; Y is selected from the group consisting of Si and P; M and M′ are selected from the group consisting of W and Mo; and n is 0-12.

It is optional that the POM cluster has a formula of H₃PW₁₂O₄₀.

Optionally, the POM cluster has a formula of X_{b}Y₂M_{n′}M′_{18-n′}O₆₂, and wherein X is a cation selected from the group consisting of H⁺, NH₄⁺, NR₄⁺ with R being a C1-C4 linear or branched alkyl; b is 6 or 8; Y is selected from the group consisting of Si and P; M and M′ are selected from the group consisting of W and Mo; and n′ is 0-18.

In an optional embodiment, the POM cluster is configured to form a discontinuous layer on the SAM.

Optionally, the POM cluster intercalates with the SAM by filling into nanovoids of the SAM.

It is optional that the SAM and the POM cluster have a concentration ratio of about 1:1 to about 1:40.

In an optional embodiment, the composite material is a hole transporting layer material.

In a second aspect of the present invention, there is provided a method for preparing the composite material in accordance with the first aspect, comprising the steps of: a) depositing a SAM of a carbazole-based compound on a substrate to form a first substrate; and b) depositing a POM cluster on the first substrate to form a discontinuous layer on the first substrate.

Optionally, step b) is carried out without pre-rinsing the first substrate.

It is optional that step b) is carried out without post-annealing.

Optionally, steps a) and b) are each carried out by way of spin-coating.

In a third aspect of the present invention, there is provided an organic solar cell comprising a hole transporting layer including the composite material in accordance with the first aspect.

In an optional embodiment, the organic solar cell further comprises: an anode and a cathode, between which the hole transporting layer is disposed; an electron transporting layer disposed between the anode and the cathode; and a photoactive layer disposed between the hole transporting layer and the electron transporting layer.

It is optional that the photoactive layer is in direct contact with the hole transporting layer and the electron transporting layer.

Optionally, the photoactive layer is configured as any one of the following structures: a bulk heterojunction, a quasi-planar heterojunction and a pseudo-bilayer.

### BRIEF DESCRIPTION OF DRAWINGS

The patent or application file contains at least one drawing executed in color. Copies of this patent or patent application publication with color drawing(s) will be provided by the Office upon request and payment of the necessary fee.

The invention will now be more particularly described, by way of example only, with reference to the accompanying drawings, in which:

FIG. 1A is a schematic diagram illustrating the Keggin structure of a polyoxometalate (POM) cluster in accordance with an embodiment of the present invention;

FIG. 1B is a schematic diagram illustrating the Dawson structure of a polyoxometalate (POM) cluster in accordance with an embodiment of the present invention;

FIG. 1C is a schematic diagram illustrating the cross-section view of an organic solar cell (OSC) in accordance with an embodiment of the present invention;

FIG. 1D shows the chemical structures of the electron donors for use in the photoactive layer in accordance with some embodiments of the present invention;

FIG. 1E shows the chemical structures of the electron acceptors for use in the photoactive layer in accordance with some embodiments of the present invention;

FIG. 2 is a schematic diagram illustrating the chemical structures of Br-PA and HPWO and the pattern of Br-PA:HPWO sequentially-deposited composite (SDC) in devices;

FIG. 3 shows the optical transmittance of ITO substrates coated with different HTLs

FIG. 4 shows the absorbance of Br-PA:HPWO SDC as a dependence of concentration of HPWO solution;

FIG. 5A shows the work function and HOMO energy level determined from UPS;

FIG. 5B shows the energy level alignment of HTL-modified ITO (work function) and PM6 (HOMO level);

FIG. 6A shows the AFM height image for fresh HTL film of single Br-PA;

FIG. 6B shows the AFM height image for fresh HTL film of HPWO;

FIG. 6C shows the AFM height image for fresh HTL film of Br-PA:HPWO SDC;

FIG. 7A shows the energy-dispersive X-ray spectroscopy (EDS) elemental mapping of Br for single Br-PA on ITO;

FIG. 7B shows the EDS elemental mapping of W for single Br-PA on ITO;

FIG. 7C shows the EDS elemental mapping of Br for Br-PA:HPWO SDC-HTL on ITO;

FIG. 7D shows the EDS elemental mapping of W for Br-PA:HPWO SDC-HTL on ITO;

FIG. 7E shows the EDS elemental mapping of the overlapping of Br and W for Br-PA:HPWO SDC-HTL on ITO;

FIG. 8 is a table summarizing the P:In intensity ratio of ITO substrates coated with different HTLs;

FIG. 9A shows the XPS spectra of In 3d_{3/2} for ITO substrates coated with Br-PA;

FIG. 9B shows the XPS spectra of In 3d_{3/2} for ITO substrates coated with HPWO;

FIG. 9C shows the XPS spectra of In 3d_{3/2} for ITO substrates coated with Br-PA:HPWO;

FIG. 10A shows the XPS spectra of P 2p core level for ITO substrates coated with single Br-PA;

FIG. 10B shows the XPS spectra of P 2p core level for ITO substrates coated with single HPWO;

FIG. 10C shows the XPS spectra of P 2p core level for ITO substrates coated with single Br-PA:HPWO SDC;

FIG. 11 shows the ESR spectra of Br-PA, HPWO, PM6, and their blends as solid powder, where g is g-factor;

FIG. 12A shows the contact angle of water on single Br-PA;

FIG. 12B shows the contact angle of water on HPWO;

FIG. 12C shows the contact angle of water on Br-PA:HPWO composite;

FIG. 13A shows the contact angle of diiodomethane on single Br-PA;

FIG. 13B shows the contact angle of diiodomethane on HPWO;

FIG. 13C shows the contact angle of diiodomethane on Br-PA:HPWO bilayer;

FIG. 14 is a table summarizing the average contact angles and surface energies of different HTLs;

FIG. 15A shows the XPS spectra and fitting curves of W 4f for ITO/HPWO;

FIG. 15B shows the XPS spectra and fitting curves of W 4f for ITO/PM6/HPWO;

FIG. 15C is a table summarizing the fitting parameters of XPS spectra of ITO/HPWO and ITO/PM6/HPWO;

FIG. 16 shows the chemical structure of ETL material employed in the devices in accordance with embodiments of the present invention;

FIG. 17 shows the PCE of HPWO-based devices as a dependence on HPWO concentration;

FIG. 18A shows the J-V curves for OSCs based on single HPWO coated from methanol solution with different concentrations;

FIG. 18B is a table summarizing the photovoltaic parameters of OSCs based on HPWO HTL coated from methanol solution with different concentrations;

FIG. 19A shows the J-V curves for devices comprising different HTLs;

FIG. 19B is a table summarizing the photovoltaic parameters of OSCs based on PM6:BTP-eC9:L8-F and different HTLs;

FIG. 20A shows the J-V curves for OSCs based on single Br-PA without solvent-rinsing or rinsed by methanol;

FIG. 20B is a table summarizing the photovoltaic parameters of OSCs based on Br-PA HTL without the treatment of solvent-rinsing or rinsed by methanol;

FIG. 21 shows the EQE spectra for devices comprising different HTLs;

FIG. 22 shows the integrated short-circuit current density for OSC devices comprising different HTLs;

FIG. 23A shows the J-V curves for OSCs based on Br-PA:HPWO HTL with HPWO coated from different concentrations in methanol;

FIG. 23B is a table summarizing the photovoltaic parameters of OSC devices using Br-PA:HPWO SDC as HTL with HPWO coated from different concentrations in methanol;

FIG. 24A shows the J-V curves for OSCs using Br-PA:HPWO mixture as HTL with different composition ratios;

FIG. 24B is a table summarizing the photovoltaic parameters of OSC devices using Br-PA:HPWO mixture as HTL with HPWO coated from different composition ratios;

FIG. 25A shows the J-V curve for large-area OSCs based on different HTLs with aperture area of 1.008 cm²;

FIG. 25B shows the performance progress of 1-cm² OSCs in recent 5 years;

FIG. 25C is a table summarizing the photovoltaic parameters for representative large-area (˜1 cm²) OSCs reported in recent 5 years;

FIG. 26 is a table summarizing the photovoltaic parameters of large-area OSCs based on different HTLs with aperture area of 1.008 cm²

FIG. 27 shows the chemical structures of the active materials for pseudo-bilayer devices in accordance with some embodiments of the present invention;

FIG. 28A shows the J-V curves for pseudo-bilayer OSCs based on different HTLs, using D18 and 3-CITh as active layer;

FIG. 28B is a table summarizing the photovoltaic parameters of pseudo-bilayer OSC devices based on different HTLs, using D18 and 3-CITh as active layer;

FIG. 29 shows the I-V curves for sandwiched devices (ITO/HTL/Ag) based on different HTLs;

FIG. 30 shows the Mott-Schottky plots @100 KHz for devices comprising different HTLs;

FIG. 31 is a table summarizing the fitting parameters obtained from Mott-Schottky plots;

FIG. 32 shows the Nyquist plots obtained from AC impedance spectra. Inset is equivalent circuit used for data fitting;

FIG. 33 is a table summarizing the fitting parameters from Nyquist plots using an equivalent circuit modeling;

FIG. 34 shows the Semi-logarithm plots of J-V plots of PM6-based devices based on different HTLs measured in the dark;

FIG. 35 shows the photocurrent density-effective voltage (Jₚₕ-V_{eff}) plots for devices comprising different HTLs;

FIG. 36 is a table summarizing the fitting parameters from dark J-V plots and Jₚₕ-V_{eff} characteristics. The Rₛ and Rₛₕ were determined around 1.5 V and 0 V, respectively, from dark J-V plots;

FIG. 37 shows the MPP tracking for devices comprising different HTLs under continuous one-sun illumination;

FIG. 38 shows the evolution of normalized PCE for devices comprising different HTLs. The parameters are average of four devices with the error depicted as standard deviation;

FIG. 39 shows the evolution of normalized FF for devices comprising different HTLs. The parameters are average of four devices with the error depicted as standard deviation;

FIG. 40 shows the evolution of normalized V_{OC} for devices comprising different HTLs. The parameters are average of four devices with the error depicted as standard deviation;

FIG. 41 shows the evolution of normalized J_{SC} for devices comprising different HTLs. The parameters are average of four devices with the error depicted as standard deviation;

FIG. 42 shows the stability aged at 65° C. for pseudo-bilayer OSCs based on different HTLs, using D18 and 3-CITh as active layer;

FIG. 43 shows the changes in work function of HTLs coated on ITO under accelerated thermal aging at 120° C. for 24 h;

FIG. 44 shows the changes in HOMO level of HTLs coated on ITO under accelerated thermal aging at 120° C. for 24 h;

FIG. 45 shows the AFM height images for fresh HTL films of single Br-PA under accelerated thermal aging at 120° C. for 24 h;

FIG. 46 shows the AFM height images for fresh HTL films of HPWO under accelerated thermal aging at 120° C. for 24 h;

FIG. 47 shows the AFM height images for fresh HTL films of Br-PA:HPWO-SDC under accelerated thermal aging at 120° C. for 24 h; and

FIG. 48 is a table summarizing the evaluation of product cost and processing complexity of different HTLs.

### DETAILED DESCRIPTION OF OPTIONAL EMBODIMENT

As used herein, the forms “a”, “an”, and “the” are intended to include the singular and plural forms unless the context clearly indicates otherwise.

The words “example” or “exemplary” used in this invention are intended to serve as an example, instance, or illustration. Any aspect or design described in this disclosure as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise or clear from context, “X employs A or B” is intended to mean any of the natural inclusive permutations. That is, if X employs A, X employs B, or X employs both A and B, then “X employs A or B” is satisfied under any of the foregoing instances.

As used herein, the phrase “about” is intended to refer to a value that is slightly deviated from the value stated herein. Examples have been described throughout the present disclosure.

It is believed that by introducing dopants such as SnCl₂ or SAM to POM-based HTLs, it may address the low conductivity of the POM-based HTLs. This, however, may lead to issue such as energy level mismatch, in particular, in the thick HTL condition. In addition, the mixing strategy may generate the problems including the tendency to phase separation, the enhanced parasitic absorption, and the sensitivity of device performance on blending ratios. Although this may be circumvented by using an ultrathin POM layer of few nanometers (under which condition the charges are extracted by tunneling), this may in turn trigger the coverage issue on anode substate with inevitably formed pin-holes or nanovoids. Such an incomplete coverage of HTL would gradually break the ohmic contact between anode and active layer under physical aging, thereby degrading the open-circuit voltage (V_{OC}) and fill factor (FF) of OSCs due to the energy-mismatch induced charge-carrier accumulation near the HTL. Thus, it is believed that a full coverage of mono-layer or ultrathin HTL on anode is essential for the efficient and stable outputs of OSCs.

Without wishing to be bound by theory, the inventors have, through their own researches, trials and experiments devised a strategy that may enable sufficient coverage of HTL under thin-film condition, thereby by-passing the necessity of using thick-film HTLs even when processed by fast-printing method. The inventors have devised that by way of sequential deposition, POM may be integrated with SAM to form an intimately intercalating composite, in particular, the SAM may be enriched at the bottom and the POM may act as both a void-filler and a top-surface passivator, resulting in improved surface profiles as well as the charge carrier density in OSC devices.

In a first aspect of the present invention, there is provided a composite material for organic solar cell (OSC) comprising a polyoxometalate (POM) cluster and a self-assembled monolayer (SAM) of a carbazole-based compound. As used herein, the term “self-assembled monolayer” or “SAM” generally denotes one molecule thick layer of material that bonds to a surface in an ordered way as a result of physical or chemical forces during a deposition process. It is appreciated that the molecule/compound which forms the one molecule thick layer may include a general structure of A-L-R, with A being a head group or an anchoring group for which the molecule/compound adsorbs (such as by way of chemisorption) onto a substrate (such as a substrate for organic solar cell); L being a tail group with a linker group on the 9-position such as a carbazole tail group with a linker of ethyl, butyl, phenyl and the like; and R being a functional group such as Cl, Br, methyl, methoxy and the like.

In particular, it is preferred that the compound of the SAM as described herein is a carbazole-based compound. In some embodiments, the carbazole-based compound may have a Formula of:

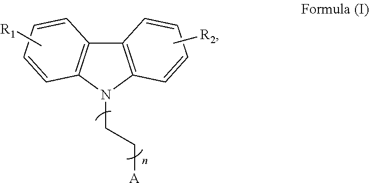

wherein: R₁ and R² each represent a mono- or di-substitutions, and are each independently selected from the group consisting of hydrogen, halogen, alkyl, alkoxy, fused ring, non-fused ring, and a combination thereof; n is a positive integer being 1-3; and A is an anchoring group including an acid moiety.

The alkyl may be linear or branched, and may be with 1-6 carbon atoms. Examples of C1-C6 linear alkyl groups may include methyl, ethyl, propyl, butyl, pentyl and hexyl. Examples of C1-10 branched alkyl groups may include isopropyl, n-butyl, isobutyl, sec-butyl, tert-butyl, n-pentyl (amyl), tert-pentyl, neopentyl, isopentyl (isoamyl), sec-pentyl, 3-pentyl, sec-isopentyl, active pentyl and the like.

As used herein, the term “alkoxy” generally denotes a functional group or substituent which includes an alkyl group that is singularly bonded to oxygen. Accordingly, the alkoxy as described herein may be those derived correspondingly from the aforementioned alkyl groups. Examples of such an alkoxyl may include methoxy, ethoxy, propoxy, butoxy, pentoxy, hexoxy, isopropoxy, n-butoxy, isobutoxy, sec-butoxy, tert-butoxy, n-pentoxy, tert-pentoxy, neopentoxy, isopentoxy, sec-pentoxy, 3-pentoxy, sec-isopentoxy and the like.

The halogen generally refers to the group 17 elements in the periodic table. Preferably, the halogen may be selected from the group consisting of F, Cl, Br, I and a combination thereof.

The fused ring and the non-fused ring may be an aryl or a heteroaryl. The aryl as described herein may have a total carbon of 6 to 10. Examples of the aryl group may include phenyl, tolyl, tert-butylphenyl, xylyl, naphthyl, indenyl, azulenyl, cumyl and the like. The heteroaryl as described herein may be those derived from a heteroaryl compound having a total carbon of 5 to 10. Examples of such a heteroaryl compound may include pyridine, indole, quinoline, isoquinoline, pyridazine, pyrimidine, benzofuran, benzo[c]thiophene, benzo[b]thiophene, isobenzofuran, quinoxaline, phthalazine, quinazoline, benzo[c][1,2,5]thiadiazole, benzo[d]isoxazole and the like.

In some embodiments, R₁ and R₂ may be each independently selected from the group consisting of H, F, Cl, Br, I, C1-C6 alkyl, C1-C6 alkoxy as described herein, C6-C10 aryl as described herein, C5-C10 heteroaryl as described herein and a combination thereof.

In some embodiments, the anchoring group A may be selected from the group consisting of carboxyl group (—C(═O)OH), sulfo group (—S(═O)₂—OH), mercapto group (—SH) and phosphono group (—P(═O)(—OH)₂).

The R₁ and R₂ may be identical or different in various embodiments of the present invention. In some embodiments where R₁ and R₂ are identical, the carbazole-based compound may have a Formula selected from the group consisting of:

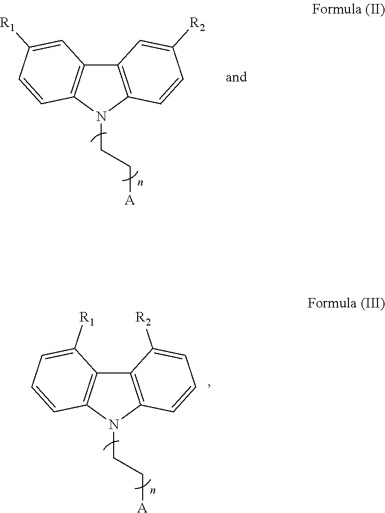

wherein: R₁ and R² each represent a mono-substitution and are selected from the group consisting of H, F, Cl, Br, I, methyl, ethyl, methoxy, ethoxy, tert-butoxy, and phenyl; n is 1-3; and A is selected from the group consisting of carboxyl group, sulfo group, mercapto group and phosphono group.

In some particular embodiments, the carbazole-based compound with identical R₁ and R₂ may have a Formula selected from the group consisting of:

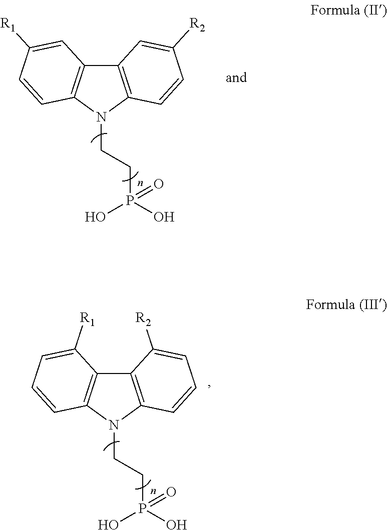

wherein R₁ and R₂ are selected from the group consisting of Br, Cl, and phenyl; and n is 1-3. In some exemplary embodiments, the carbazole-based compound with identical R₁ and R₂ may have a Formula selected from the group consisting of:

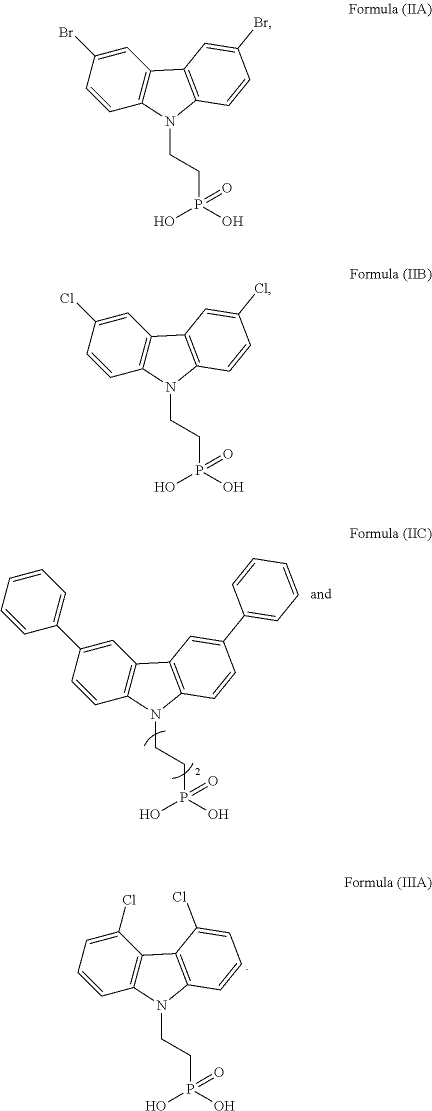

In some embodiments where R₁ and R₂ are different, the carbazole-based compound may have a Formula selected from the group consisting of:

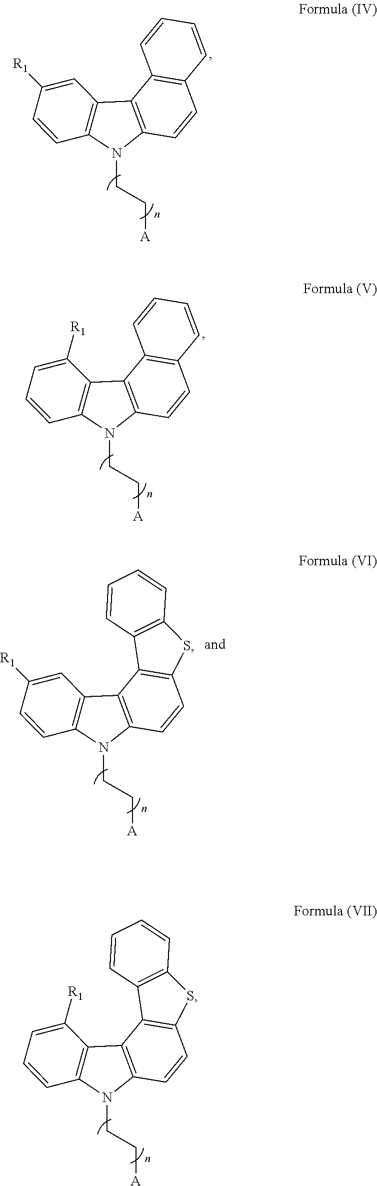

wherein: R₁ represents a mono-substitution and is selected from the group consisting of H, F, Cl, Br, I, methyl, ethyl, methoxy, ethoxy, tert-butoxy, and phenyl; n is 1-3; and A is selected from the group consisting of carboxyl group, sulfo group, mercapto group and phosphono group.

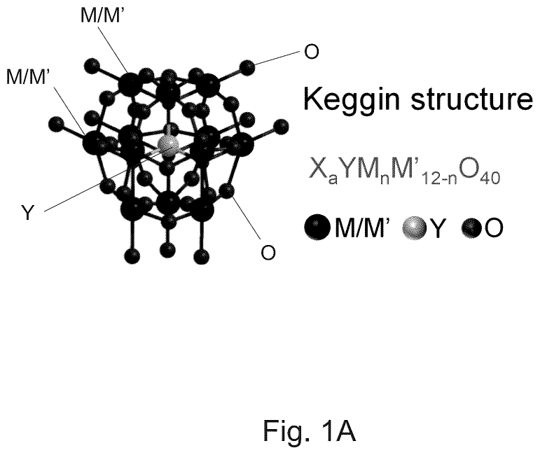

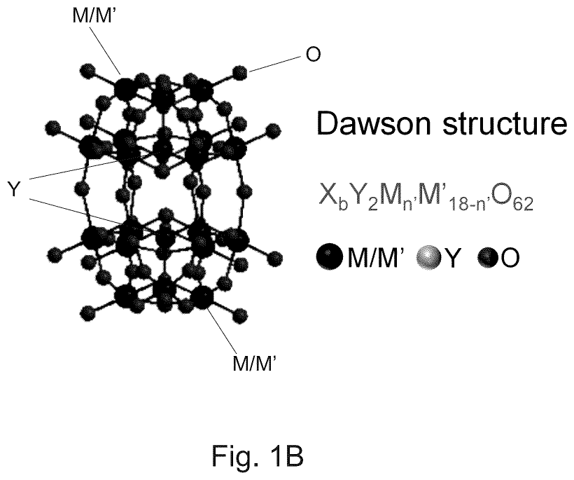

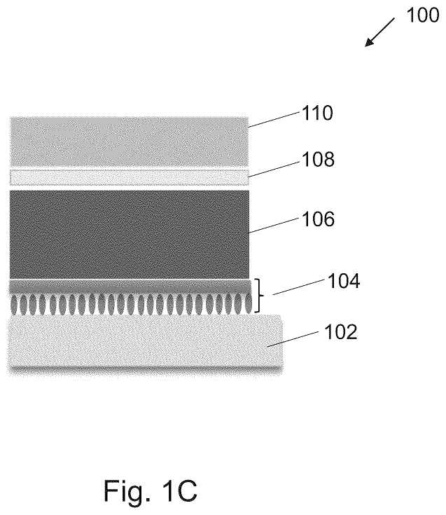

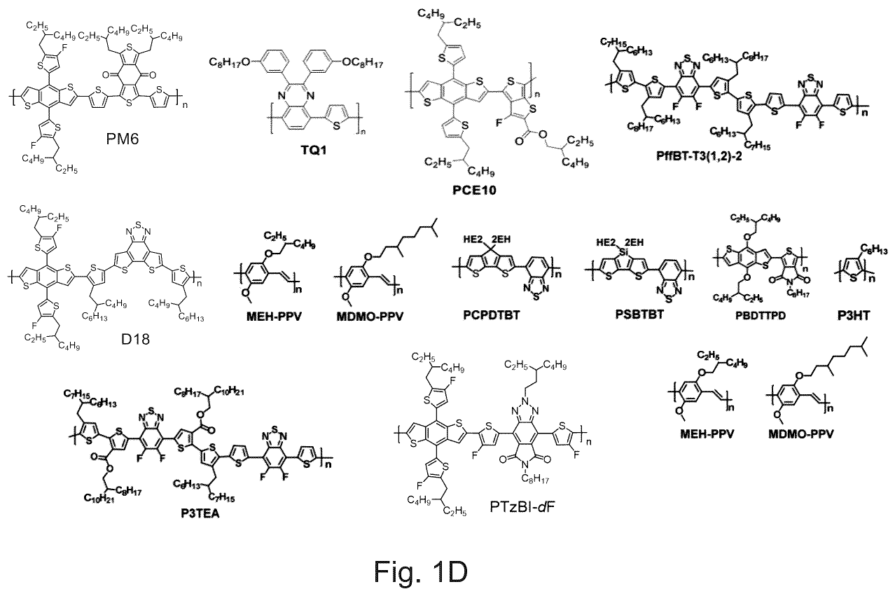

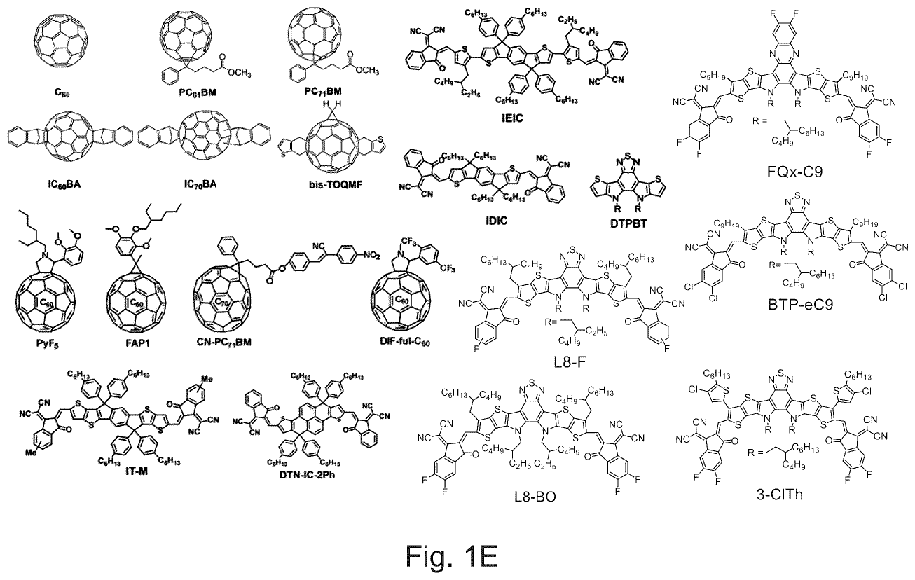

In some embodiments, the POM cluster may comprise a Keggin structure. With reference to FIG. 1A, the Keggin structure may have a full tetrahedral symmetry and may be composed of one heteroatom Y surrounded by four oxygen atoms to form a tetrahedron. The heteroatom Y may be located centrally and caged by 12 octahedral MO₆ and/or M′O₆ units linked to one another by the neighboring oxygen atoms. In some particular embodiments, the POM cluster having a Keggin structure may have a formula of XₐYMₙM′₁₂₋ₙO₄₀, and wherein X may be a cation selected from the group consisting of H⁺, NH₄⁺, NR₄⁺ with R being a C1-C4 linear or branched alkyl as described herein; a is 3 or 4; Y is selected from the group consisting of Si and P; M and M′ are selected from the group consisting of W and Mo; and n is 0-12.

In an example embodiment, the POM cluster having a Keggin structure may have a formula of H₃PW₁₂O₄₀.

In some embodiments, the POM cluster may comprise a Dawson structure. With reference to FIGS. 1A and 1B, the Dawson structure may be considered as a fusion of two defect Keggin structures, with three missing octahedra. The Dawson structure may include two oxyanions Y at its core, one at each side of the ellipsoidal anion. In some particular embodiments, the POM having a Dawson structure may have a formula of X_{b}Y₂M_{n′}M′_{18-n′}O₆₂, and wherein X is a cation selected from the group consisting of H⁺, NH₄⁺, NR₄⁺ with R being a C1-C4 linear or branched alkyl as descried herein; b is 6 or 8; Y is selected from the group consisting of Si and P; M and M′ are selected from the group consisting of W and Mo; and n′ is 0-18.

As mentioned above, it is advantageous that the POM cluster as descried herein may act as a void filler and surface passivator for the SAM. In particular, the POM cluster may be configured to form a discontinuous layer on the SAM. Without wishing to be bound by theory, the inventors have devised that by way of, for example, sequential deposition of the POM cluster onto the SAM, the POM cluster may intercalate with the SAM by filling into nanovoids of the SAM, thereby a discontinuous passivator layer (of the POM cluster) is formed on top of the SAM that is enriched at the bottom. It is also believed that such a structural arrangement may be advantageous in increasing efficiency as well as long-term stability of the organic solar cells when the composite material is used in a hole transport layer. Accordingly, in some embodiments, the composite material may be a hole transporting layer material.

In some embodiments, the POM cluster and the SAM may have a concentration ratio of about 1:1 to about 1:40, such as 1:0.9, 1:0.91, 1:0.92, 1:1, 1:1.01, 1:1.02, 1:39.6, 1:39.7, 1:39.9, 1:40.1, 1:40.2, 1:40.3 and the like.

The method for preparing the composite material as described herein will now be disclosed. The method may involve a sequential deposition of the SAM and the POM cluster on a substrate such as a conductive substrate (e.g., ITO glass). In some embodiments, the method may comprise the steps of a) depositing a SAM of a carbazole-based compound as described herein on a substrate to form a first substrate; and b) depositing a POM cluster on the first substrate to form a discontinuous layer on the first substrate. In particular, steps a) and b) may be each carried out by way of spin-coating. For example, a SAM precursor solution which contains the carbazole-based compound as described herein and a suitable solvent such as an alcohol (e.g., isopropanol and the like) may be spin coated on an ITO glass at a speed of, e.g., about 2800 rpm to about 3200 rpm, about 2850 rpm to about 3200 rpm, about 2790 rpm to about 3200 rpm, about 2900 rpm to about 3150 rpm, about 2900 rpm to about 3010 rpm, about 2950 rpm to about 3000 rpm and the like, for about e.g., about 25 seconds to about 30 seconds to about 24 seconds to about 31 seconds, about 25 seconds to about 29 seconds, about 28 seconds to about 30 seconds and the like, to form a first substrate. After that, the first substrate may be spin-coated with a POM precursor solution containing the POM cluster as described herein and a suitable solvent such as an alcohol (e.g., methanol and the like) at a speed of, e.g., about 3800 rpm to about 4200 rpm, about 3850 rpm to about 4200 rpm, about 3800 rpm to about 4250 rpm, about 3800 rpm to about 4100 rpm, about 3900 rpm to about 4050 rpm, about 3950 rpm to about 4000 rpm and the like, for about, e.g., about 25 seconds to about 30 seconds to about 24 seconds to about 31 seconds, about 25 seconds to about 29 seconds, about 28 seconds to about 30 seconds and the like.

Preferably, step b) of the method as described herein is carried out without pre-rinsing the first substrate. In other words, after the first substrate is obtained, step b) is immediately carried out to spin-coat the POM cluster precursor solution onto the first substrate. Without wishing to be bound by theory, it is believed that any excess carbazole-based compounds that are not chemisorbed by the substrate in step a) would be eventually removed by the solvent of the POM precursor solution in step b). Advantageously, it is believed that the above would reduce the processing complexity for preparing the composite material as described herein.

Without wishing to be bound by theory, it is believed that a dense layer of the composite material may be formed after step b). Thus, in some preferred embodiments, step b) may be carried out without post-annealing. In other words, after the spin-coating in step b) is completed, post-annealing to the as-formed composite material is not required. Advantageously, it is believed that the above would further reduce the processing complexity for preparing the composite material as described herein.

As mentioned, the composite material as described herein is particularly useful in organic solar cells, such as being used as a hole transporting layer for organic solar cells. Accordingly, in a third aspect of the present invention, there is provided an organic solar cell comprising a hole transporting layer including the composite material as describe herein.

With reference to FIG. 1C, there is provided a cross-sectional view illustrating a structure of an organic solar cell (OSC) 100 in accordance with an embodiment of the present invention. Referring to FIG. 1C, the OSC in this embodiment includes an anode 102, a hole transporting layer (HTL) 104, a photoactive layer 106, an electron transporting layer 108 and a cathode 110.

The anode 102 may be made of any suitable material that can be used in OSCs. In some embodiments, the anode may a metal piece such as a metal plate of Au, Cu and the like. In some other embodiments, the anode may comprise a substrate onto which a conductive material is deposited. Examples of such an anode may include ITO glass, IZO glass, FTO glass, AZO glass and the like.

The HTL 104 may be disposed between the anode 102 and the photoactive layer 106, particularly is in direct contact with the anode and the photoactive layer. The HTL may be formed by depositing, particularly spin-coating, more particularly sequential depositing/spin-coating the SAM and the POM cluster onto the anode, using the preparation method as described herein. In some example embodiments, the HTL 104 may be prepared by spin-coating the SAM onto the anode, followed by thermal annealing and further spin-coating with the POM cluster to form a HTL having a bilayer structure (i.e., a discontinuous layer of the POM cluster on top of the SAM that is enriched at the bottom as described herein).

The photoactive layer 106 may be disposed between the HTL 104 and the ETL 108, particularly in direct contact with the HTL and the ETL. The photoactive layer may include at least one electron donor and at least one electron acceptor. Examples of the electron donor may include one or more of the compounds as illustrated in FIG. 1D. Examples of electron acceptor may include one or more of the compounds as illustrated in FIG. 1E.

In some embodiments, the photoactive layer may be configured as one of the following structures: a bulk heterojunction (BHJ), a quasi-planar heterojunction (QPHJ) and a pseudo-bilayer. The photoactive layer may be formed by one-step spin-coating of a donor-acceptor blend solution, sequential spin-coating of the neat solutions of the donor and the acceptor, etc.

The ETL 108 may be formed on, particularly in direct contact with the photoactive layer, such as by way of spin-coating. The ETL may be formed of a material having high electron-transport capability. Examples of such a material may include 2,9-bis(3-(bis(2-hydroxyethyl)amino)propyl)anthra[2,1,9-def:6,5,10-d′e′f′]diisoquinoline-1,3,8,10(2H,9H)-tetraone (PDINOH), poly[(9,9-bis(3′-(N,N-dimethylamino)propyl)-2,7-fluorene)-alt-2,7-(9,9-dioctylfluorene)](PFN) and the like.

The cathode 110 is formed on, particularly in direct contact with the ETL 108, such as by way of vacuum deposition. Examples of suitable cathode material may include Ag, Al, Zn and the like.

As mentioned herein, the composite material as described herein is particularly useful in organic solar cells and is advantageous in increasing efficiency as well as long-term stability of the organic solar cells when the composite material is used in a hole transport layer. For example, as shown in Table 1 below, the organic solar cells with a hole transporting layer having the composite materials as described herein may result in a power conversion efficiency (PCE) of about 18.3% to about 19.4%.

TABLE 1
Power Conversion Efficiency of OSC Devices with Hole Transporting
Layers having the Composite Materials as described herein

| Photoactive layer | HTL | PCE (%) |
|---|---|---|
| PM6:BTP-eC9:L8-F | Formula (IIA):HPWO | 19.10 |
| D18:3-ClTh | Formula (IIB):HPWO | 18.31 |
| D18:L8-BO | Formula (IIC):HPWO | 19.40 |
| D18:FQx-C9 | Formula (IIIA):HPWO | 18.64 |

*HPWO = phosphotungstic acid hydrate

Detailed performance of the OSC described herein will be discussed in the later part of the present disclosure.

Hereinafter, the present invention is described more specifically by way of examples, but the present invention is not limited thereto.

### EXAMPLES

### Materials and Methods

### Materials

The photoactive materials, PM6 and BTP-eC9, and the SAM, Br-PA, were purchased from Organtec Ltd. L8-F was purchased from Hyper Chemical Inc. PDINOH was synthesized according to the reported method. The POM, HPWO (phosphotungstic acid hydrate), was purchased from Sigma-Aldrich with the reagent grade (purity≥99.5%). The HPWO was not dehydrated before using because the removing of water of crystallization needs a harsh annealing condition at 300° C. for 1 h and the dehydration can inevitably result in the formation of tiny holes in the solid electrolyte.

### Solar Cell Fabrication

OSC devices were fabricated using a p-i-n structure of ITO/HTL/active layer/PDINOH/Ag. Pre-cleaned ITO (130 nm) glasses were treated with oxygen plasma (50 W) for 30 min.

For the single SAM HTL, Br-PA in isopropanol (0.5 mg mL⁻¹) was spin-coated onto ITO at 3000 rpm for 30 s in air followed by thermal annealing at 100° C. for 5 min. The cooled substrates were rinsed by isopropanol or methanol at 3000 rpm for 30 s in air followed by another annealing at 100° C. for 5 min.

For the single POM HTL, HPWO in methanol (0.5-5 mg mL⁻¹) was spin-coated on ITO at 4000 rpm for 30 s in nitrogen-filled glove box without any post-treatments.

For the SAM:POM composite HTL, Br-PA in isopropanol (0.5 mg mL⁻¹) was first spin-coated onto ITO at 3000 rpm for 30 s in air. After transferred into glove box, the substrates were spin-coated with HPWO (0.5 mg mL⁻¹ in methanol) directedly at 4000 rpm for 30 s without pre-rinsing by pure solvent or post-annealing.

The blends of PM6:BTP-eC9:L8-F (weight ratio: 1:0.9:0.3) were dissolved in chloroform with donor concentration of 7.8 mg mL⁻¹ and stirred at 50° C. for >1 h. A small amount of diiodooctane (0.32 vol %) was added into the solution 10 min ahead of deposition. The blend solution was spin-coated on the substrates at 3500 rpm for 35 s, giving an active layer with thickness of ˜100 nm. Thermal annealing at 85° C. for 5 min was performed for the active layers. For pseudo-bilayer devices, D18 was dissolved in chlorobenzene with a concentration of 6 mg mL⁻¹, which was heated at 90° C. before spin-coated onto hot substrates at 3000 rpm for 30 s. 3-CITh in chloroform solution (11 mg mL⁻¹) without solid additive were coated atop at 2800 rpm to form a pseudo bilayer with thickness of ˜110 nm. After thermally annealed at 80° C. for 2 min, the substrates were rinsed by ethanol (50 μL) at 2800 rpm for 20 s. A thin layer (˜10 nm) of PDINOH was then coated atop from its trifluoroethanol solution (1.5 mg mL⁻¹) at 2800 rpm for 20 s.¹ Finally, silver (Ag) with thickness of 100 nm was deposited in a vacuum of 5×10−6 torr through a shadow mask of 4.14 mm².

For accuracy, a non-refractive mask was used to further define the device effective area as 3.30 mm² during J-V measurements. For larger-area devices, ITO substrates with dimension of 2.5×2.5 cm² were used for the device fabrication. The active layer and transporting layers were spin-coated onto the substrates under the same conditions as those in the small-area situation. The device effective area is determined as 1.09 cm² by the shadow mask in the silver deposition, with the aperture area refined as 1.008 cm².

### Instruments and Characterizations

Absorption and transmission spectra were recorded on a SHIMADZU UV-1700 spectrophotometer. Tapping-mode atomic force microscope (AFM) was performed on a Bruker MultiMode 8-HR AFM platform with an imaging Z-noise level less than 30 pm. Energy-dispersive X-ray spectroscopy (EDS) elemental mapping was performed on a high-resolution environmental scanning electron microscope (FEI/Philips XL30 Esem-FEG) equipped with an EDS system using an accelerating voltage of 15 KV. Contact angle measurements were performed on a Dataphysics OCA40 Micro surface contact angle analyzer using deionized water and diiodomethane as the wetting liquid.

Surface energy (γ) was evaluated based on the Owens-Wendt-Rabel-Kaelble (OWRK) methodology. The γ^{d} and γ^{p} represent the surface energy from the dispersion and polar force, respectively. X-ray photoelectron spectroscopy (XPS) and ultraviolet photoelectron spectroscopy (UPS) were performed on Thermo Fisher ESCALAB QXi X-ray Photoelectron Spectrometer. Non-monochromatic He I was used as the ultraviolet light source with an energy of 21.21 eV. The basic vacuum of the analysis chamber is ˜2×10⁻⁹ mbar, and the bias voltage applied during the test is −5 V. Electron spin resonance (ESR) was recorded on a Bruker A300/E500 ESR spectrometer at 298 K with the protection of nitrogen. The neat materials of Br-PA, HPWO, and PM6 were measured directly using the powder sample. The Br-PA:HPWO sample was prepared by blending the fine powders of two materials together with weight ratio of 1:1. The PM6:HPWO (1:1) sample was obtained by initially dissolving PM6 and HPWO into chloroform and methanol, respectively, followed by blending the solutions and dried thoroughly in vacuum.

Mott-Schottky plots were measured on an all-in-one platform of Paios (Fluxim AG) under a fixed frequency of 100 KHz. Electrochemical impedance spectra (EIS) were measured on a CHI760E electrochemical workstation (NBeT group, Beijing). The AC impedance measurements were done in Z-θ mode for a varying frequency (100 to 100 KHz) with an AC drive bias of 5 mV. A constant DC bias equivalent to V_{OC} of solar cells was applied, superimposed on the AC bias. J-V curves were measured under a computer controlled Keithley 2400 source-meter under 1 sun, AM 1.5 G solar simulator (Enlitech SS-F5). Light intensity was calibrated by a standard silicon reference cell certified by NREL and Fraunhofer to give a value of 100 mW cm⁻². EQE spectra were measured on an Enlitech QE-S system equipped with a standard silicon diode, where the monochromatic light was generated from a Newport 300 W lamp. Dynamic MPP tracking was recorded on an in-situ stability measurement system (CRYSCO, Guangzhou) equipped with multiple sample chambers and automatic data picking elements. The sample chamber was placed in the nitrogen-filled glove box with the testing devices unencapsulated during the measurement. A white LED lamp with tunable light intensity was used as the light source and an extra optical filter was loaded to cut off the UV light.

Electrical conductivity (c) was measured according to the Pouillet's law, σ= (I/V) (L/S), where V is the voltage, I is the current through the HTL film, L is the thickness of HTL film, and S is the area of the device. The measurements were performed using a sandwiched structure of ITO/HTL/Ag under dark condition. All the HTL films have a thickness of ˜30 nm. PEDOT:PSS was deposited from its aqueous solution (Heraeus) at 3000 rpm. Br-PA was made into a bulk film (rather than mono-layer) from its isopropanol solution (10 mg mL⁻¹) at 3000 rpm. HPWO was spin-coated from its methanol solution (10 mg mL⁻¹) at 4000 rpm. The Br-PA:HPWO mixture (2:1, weight ratio) was spin-coated from its isopropanol solution (10 mg mL⁻¹) at 3500 rpm.

### Example 1

### Preparation and Properties of SDC-HTL

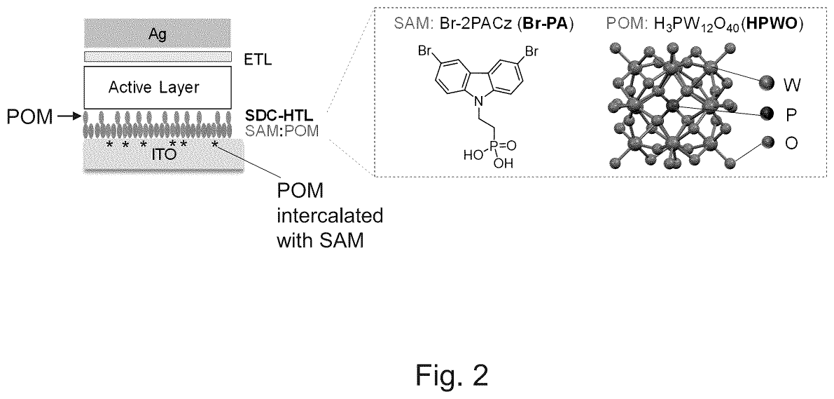

The deposition procedure of the SDC-HTL composed of sequentially coated Br-PA and HPWO (FIG. 2). HPWO was selected as post-coating layer because its zero-dimensional nanostructure could fill into the vacancies in the Br-PA bottom layer. The oxygen atoms on the peripheral of HPWO framework could anchor the ITO surface through the vacancies, therefore increasing the surface coverage and inhibiting the possible swing of tail groups of Br-PA under thermal stress.

Both the Br-PA and HPWO were spin-coated from dilute alcohol solutions. Since the phosphonic acid group of Br-PA can strongly anchor onto the ITO substrate, HPWO can be coated atop by non-orthogonal solvent without causing severe damage to the bottom Br-PA layer. The Br-PA sub-layer in the SDC-HTL was not rinsed by any solvent, because the excess Br-PA molecules that are not chemisorbed by ITO could be in principle washed away by the alcohol solution of HPWO. Therefore, the SDC-HTL strategy would not increase the processing complexity compared with the deposition of single Br-PA HTL that requires an extra rinse by pure solvent.

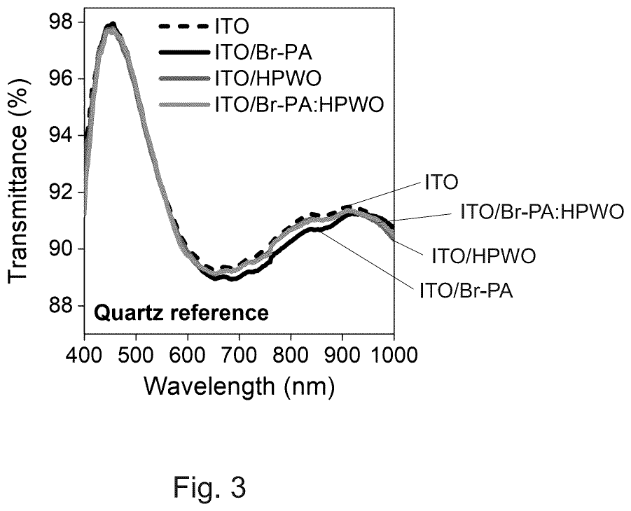

The transmittance of ITO substrates coated with different HTLs were measured by ultraviolet-visible spectroscopy with quartz as reference (FIG. 3). All the substrates show a similarly high transmittance >89% in the whole range between 400-1000 nm. However, in the NIR region (650-950 nm), the ITO/Br-PA exhibits slightly decreased transmittance (˜0.5%) with respect to that of bare ITO, while there is no discernable change in the transmission of ITO/HPWO compared to that of ITO. Interestingly, the transmission of Br-PA:HPWO composite is slightly higher than that of single Br-PA. This should be the result of partial replacement of chemisorbed Br-PA layer by HPWO during the SDC-HTL formation (see the HTL pattern illustrated in FIG. 2), suggesting the SDC-HTL strategy would not increase the parasitic absorption when employed in solar cells.

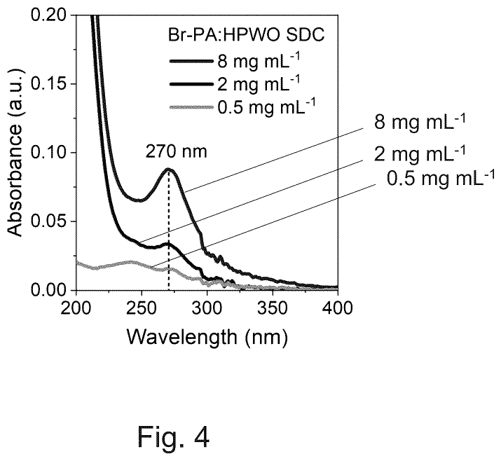

The thickness of the ultra-thin SDC-HTL was roughly evaluated by combining the step profiler measurement with the extrapolation from an absorbance-thickness relationship that assumes a linear dependence of the absorbance on the film thickness. The absorbance of SDC films coated from different HPWO concentrations (from 0.5 to 8 mg mL⁻¹ while with that of Br-PA fixed as 0.5 mg mL⁻¹) was shown in FIG. 4. By comparing the absorbance of characteristic peak at 270 nm and measuring the thickness of 8 mg mL⁻¹-film via step profiler (˜20 nm), the 0.5 mg mL⁻¹-film is extrapolated as ˜3.4 nm.

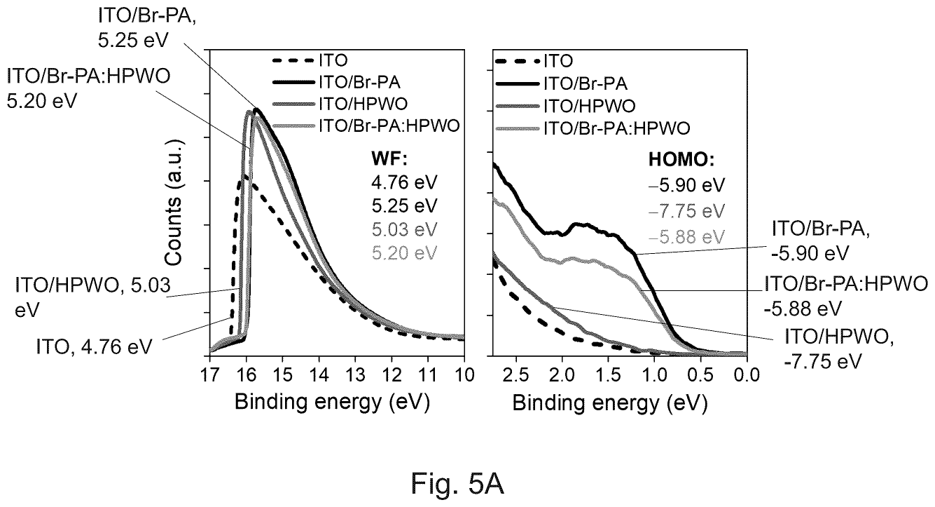

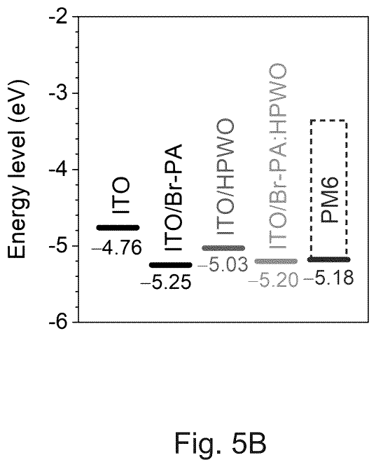

FIG. 5A shows the ultraviolet photoelectron spectroscopy (UPS) of different HTLs on ITO. The Fermi level was determined from linearly extrapolating the high binding-energy (BE) portion of the spectra. All the HTLs lead to a significant increase in WF (5.03-5.25 eV) compared with that of bare ITO (4.76 eV), confirming a great potential of these HTLs to form a better energy level alignment between the anode and the active layer (FIG. 5B). Specifically, the Br-PA-coated ITO exhibits a higher WF (5.25 eV) than that of ITO coated with single HPWO (5.03 eV), while the Br-PA:HPWO SDC has a medium WF of 5.20 eV. By further extracting the UPS onset in the low BE region, the HOMO energy level of ITO/Br-PA and ITO/Br-PA:HPWO was calculated to be −5.90 and −5.88 eV, respectively. The slightly up-shifted HOMO level of SDC-HTL could mitigate the potentially blocked hole extraction by the interfacial layer in case it is made into a thick film.

### Example 2

### Component Distribution in SDC-HTL

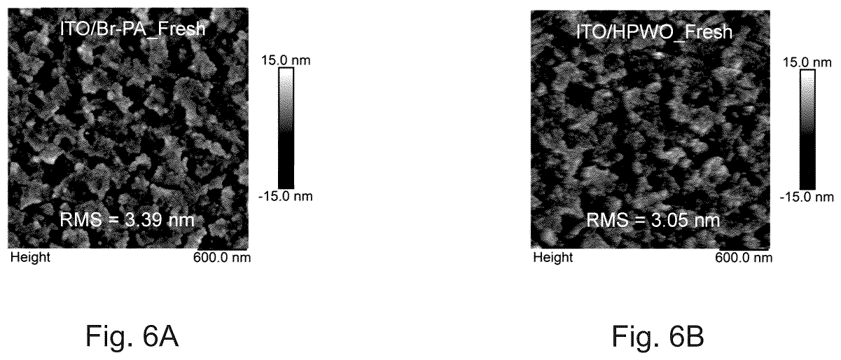

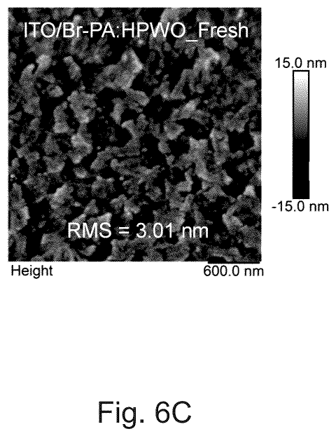

The surface profile of ITO substrates coated with different HTLs were investigated by atomic force microscopy (AFM). The Br-PA-modified ITO shows a clear topography with sharp contrast and a high root-mean-square roughness (RMS) of 3.39 nm, while the ITO/HPWO presents a smaller feature size with relatively lower RMS of 3.05 nm (FIGS. 6A and 6B). This implies the HPWO single layer can already be a decent surface passivator of ITO. The Br-PA:HPWO film shows a smoother surface with even lower RMS than that of neat HPWO (FIG. 6C), implying the HPWO is not simply overlayed on top of Br-PA, but mainly intercalates into the Br-PA layer, therefore forming a better coverage on ITO. This also indicates that a better interfacial contact between the SDC-HTL and active layer could be formed.

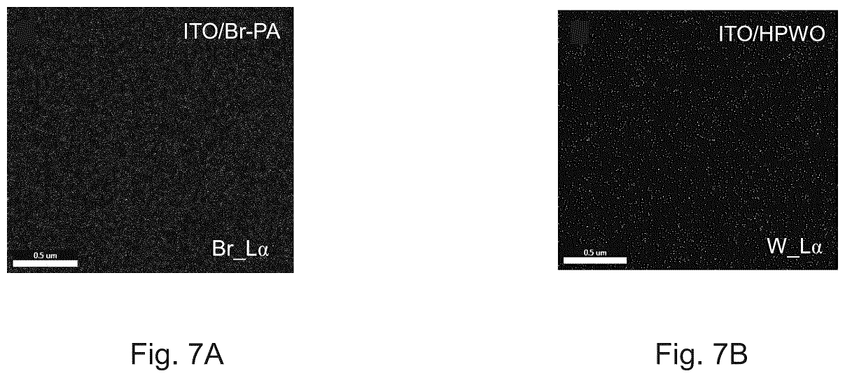

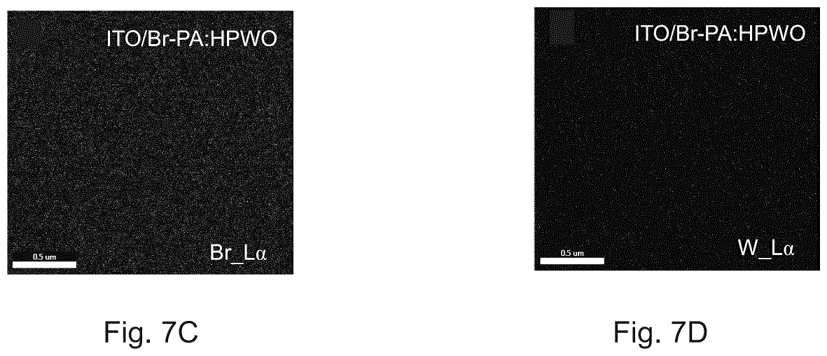

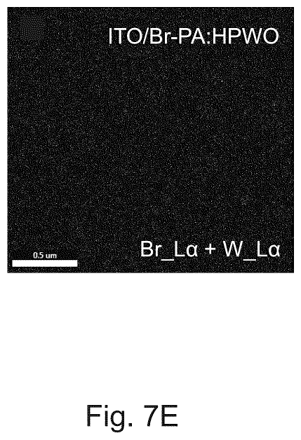

The energy-dispersive X-ray spectroscopy (EDS) elemental mapping was performed on a high-resolution scanning electron microscope (SEM). The specific X-ray energy and strength of La emission for bromine (Br) and tungsten (W) were detected to map the distribution of Br-PA and HPWO, respectively, within a region of 2.5×2.5 μm². For single-layer HTLs of both Br-PA and HPWO, the component is homogeneously distributed on ITO (FIGS. 7A and 7B). However, the easily observed vacancies and pin-holes in single layers (especially HPWO film) confirm the incomplete coverage of these ultra-thin HTLs on ITO. This is somewhat relieved in the SDC-HTL where the Br-PA and HPWO intercalates to form a dense film (FIGS. 7C-7E).

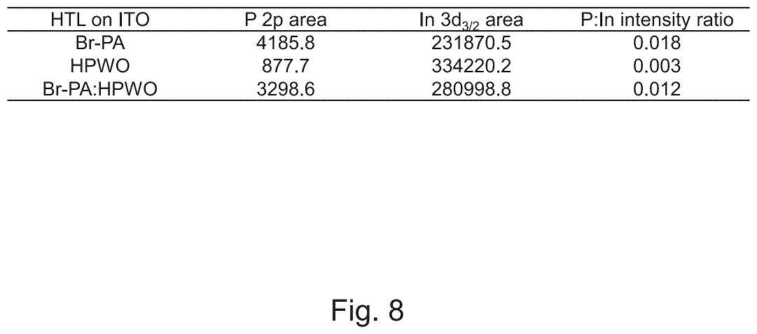

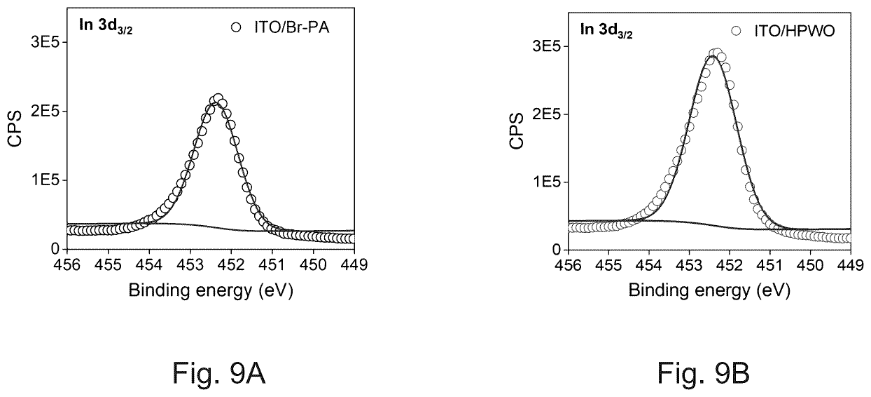

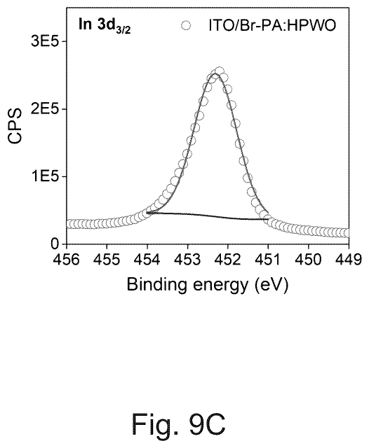

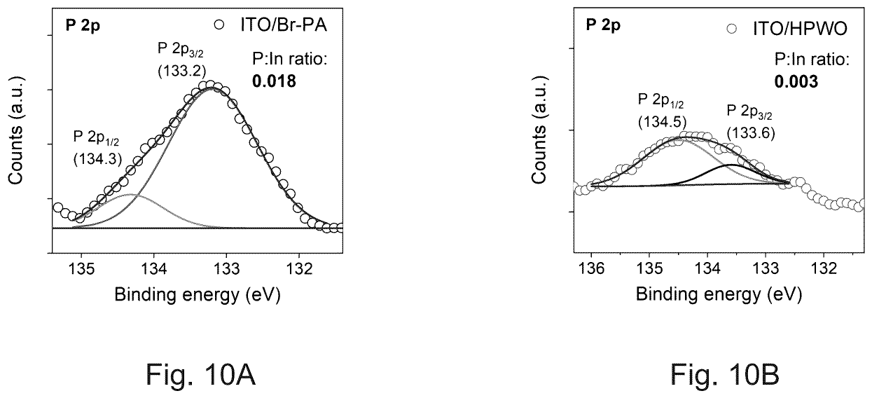

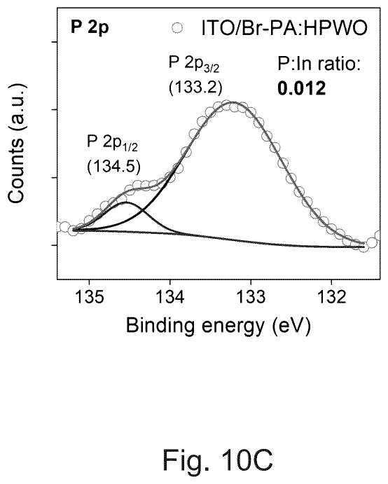

X-ray photoelectron spectroscopy (XPS) was further utilized to reveal the coverage and pattern of HTLs on ITO. The peaks of P 2p and In 3d_{3/2} belonging to Br-PA (or HPWO) and ITO substrate, respectively, were fitted to determine the relative content of Br-PA and/or HPWO molecules on ITO. The fitted peak areas are summarized in FIG. 8, where the P:In intensity ratio is obtained from the P 2p: In 3d_{3/2} peak area ratio (see the fitting of In 3d_{3/2} peak in FIGS. 9A-9C). The single Br-PA shows much higher P:In intensity ratio (0.018) than that of 0.003 for single HPWO (FIGS. 10A and 10B). Moreover, the P:In intensity ratio is 0.012 for the Br-PA:HPWO composite (FIG. 10C), lower than that of single Br-PA.

Considering that the composite was obtained from sequential deposition, it should have two possible distribution patterns. One is the overlayed pattern with HPWO molecules totally on top of the bottom Br-PA layer, with the other being the intercalated pattern that Br-PA molecules enrich at the bottom and HPWO clusters fill in the vacancies of bottom Br-PA layer while forming another discontinuous passivator layer on top. Based on the lower P:In ratio of Br-PA:HPWO SDC layer than that of single Br-PA layer, it is rationally inferred that the composite takes the latter pattern as depicted in FIG. 2.

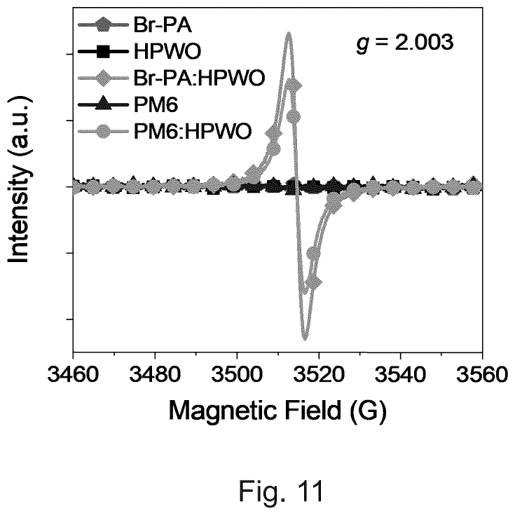

To figure out if HPWO can be doped by Br-PA in the composite, electron spin resonance (ESR) was investigated for neat powders of Br-PA and HPWO, as well as their blend, Br-PA:HPWO (1:1, weight ratio). Comparing with the neat samples showing only horizontal lines in the ESR spectra (FIG. 11), an intense ESR signal with a g-factor of 2.003 (i.e., unpaired electron) is observed for Br-PA:HPWO blend, indicating the electron transfer could happen in the Br-PA:HPWO composite HTL.

### Example 3

Interaction of SDC-HTL with Active Layer

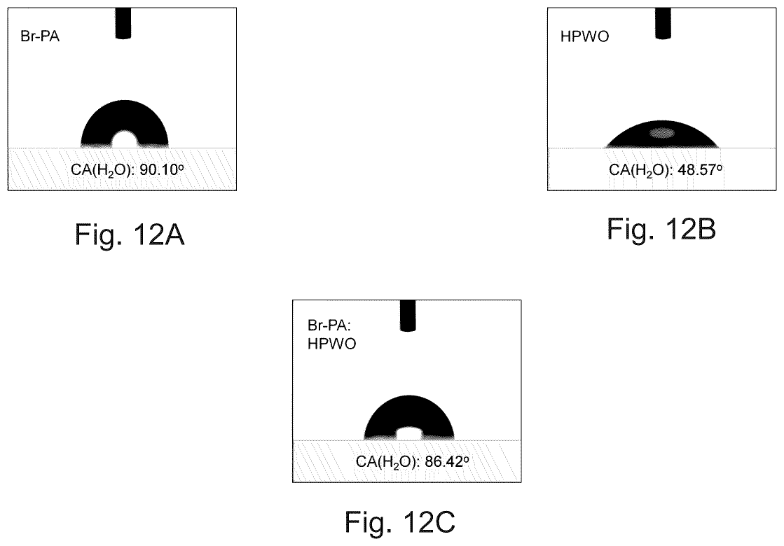

The surface wettability of different HTLs was investigated by contact angle measurements. The contact angle of water for Br-PA mono-layer is almost two times of that for HPWO film (90.1° vs. 48.6°, FIGS. 12A and 12B). The increased hydrophilicity of HPWO is basically not favorable for the long-term stability of OSCs since the water resistance should be decreased. However, the Br-PA:HPWO SDC exhibits a water contact angle (86.4°, FIG. 12C) close to that of single Br-PA, indicating a much less water wettability compared with single HPWO.

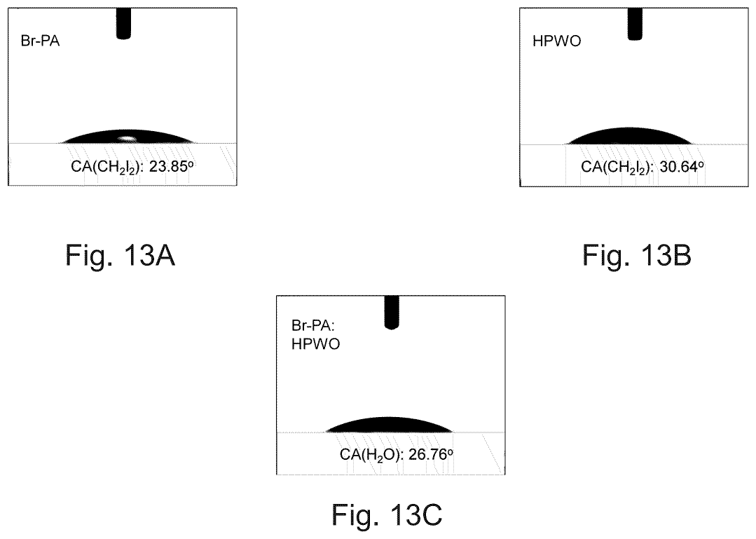

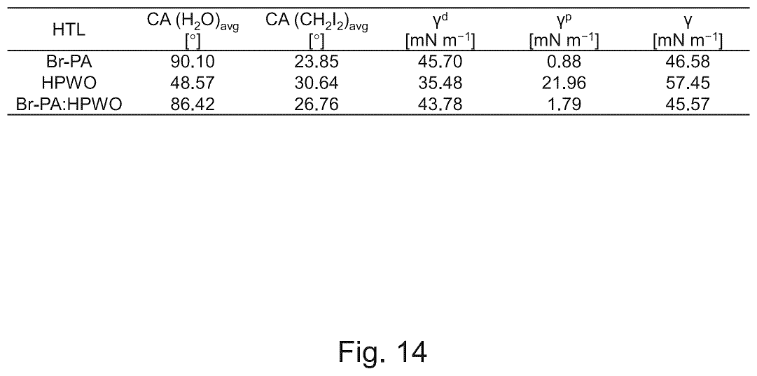

Combined with the contact angle of diiodomethane (CH₂I₂, FIGS. 13A-13C), the surface energy (γ) including the dispersive (γ^{d}) and polar (γ^{p}) components of different HTLs are calculated by the Owens-Wendt-Rabel-Kaelble method. It is noted the proportion of polar component is much higher for HPWO film, giving a highest γ of 57.5 mN m⁻¹ among all HTLs (FIG. 14). Compared with single Br-PA, the Br-PA:HPWO composite shows slightly increased γ^{p} but concomitantly reduced γ^{d}, resulting in a slightly lower γ of 45.6 mN m⁻¹ than that of 46.6 mN m⁻¹ for the former. This could be beneficial for enriching polymer donor that usually has a lower surface energy (than that of non-fullerene acceptors) at the bottom surface of active layer.

It is believed that POM clusters have deep-lying lowest occupied molecular orbital (LUMO) energy level, which makes them easily reduced with the additional electron going into their metallic orbitals. Thus, the possible p-doping between HPWO and polymer donor, PM6, was investigated by ESR. From the spectra illustrated in FIG. 11, an obvious ESR response can be observed for PM6:HPWO blend, while those of neat PM6 and HPWO powders are absent, confirming the occurrence of electron transfer from PM6 to HPWO.

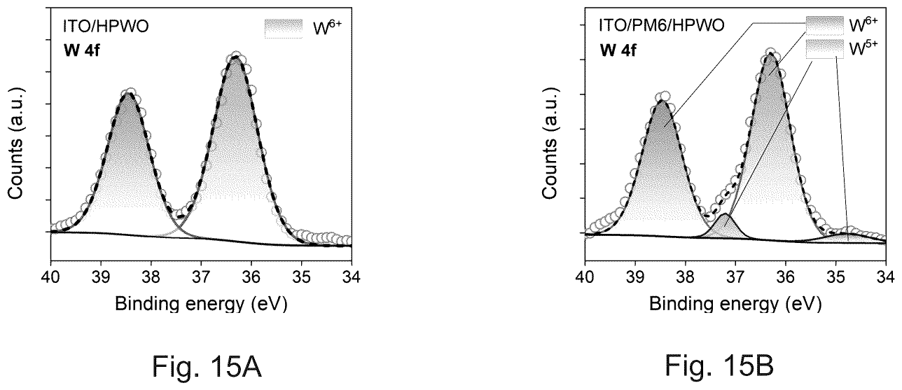

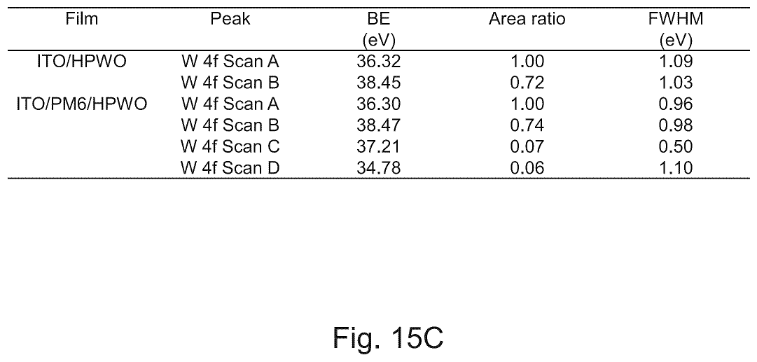

This doping behavior was further verified by monitoring the oxidation states of W 4f core level through XPS. FIGS. 15A and 15B show the XPS spectra of HPWO film (from 1 mg mL⁻¹ methanol solution) deposited on bare ITO and ITO/PM6 (˜50 nm). The deconvolution of W 4f photoemission peaks for ITO/HPWO generates two peaks of nearly equal full width at half maximum (FWHM) with the binding energy (BE) of W 4f_{5/2} centered at 38.5 eV and that of W 4f_{7/2} at 36.3 eV (FIG. 15C). They are believed to belong to the oxidation state W6⁺ as evaluated from the position and shape of these peaks. In the presence of PM6 (i.e., ITO/PM6/HPWO), except for the two main peaks at 38.5 eV and 36.3 eV, two extra peaks centered at lower BE of 37.2 eV (W 4f_{5/2}) and 34.8 eV (W 4f_{7/2}) become evident. This is a clear indication of presence of W5⁺ ions obtained from reduction of HPWO by PM6, confirming the p-doping between PM6 and HPWO.

### Example 4

Performance of Solar Cells with Varied HTLs

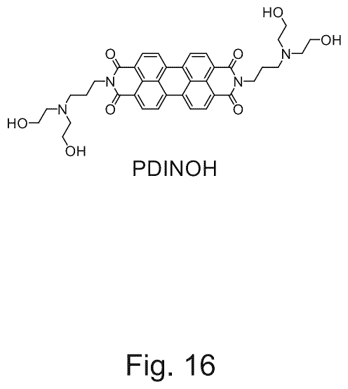

p-i-n Solar cells with active layer of PM6:BTP-eC9:L8-F were fabricated to reveal the impact of HTL on device performance. The guest acceptor L8-F with weight ratio of 1:3 relative to the host acceptor BTP-eC9 was included as a phase modifier. A small molecule, PDINOH (FIG. 16), containing hydroxyethyl-based branched side-chains was used as the electron-transporting layer (ETL) for all the devices, given the possible anti-aggregation effect of the branched side-chains may benefit the long-term stability of devices.

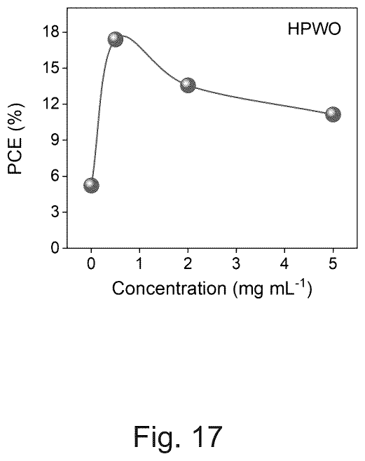

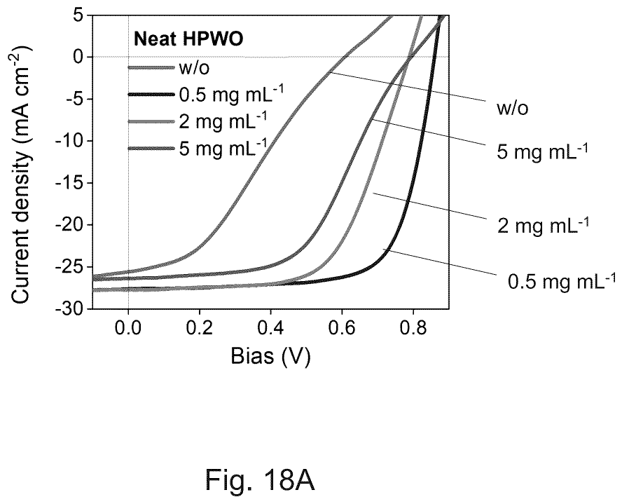

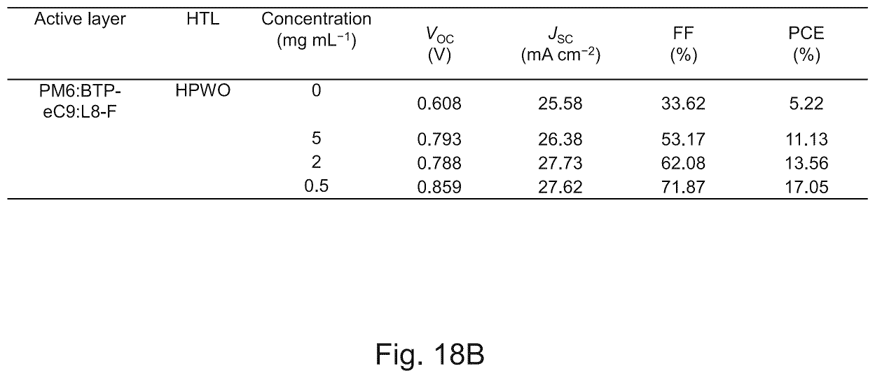

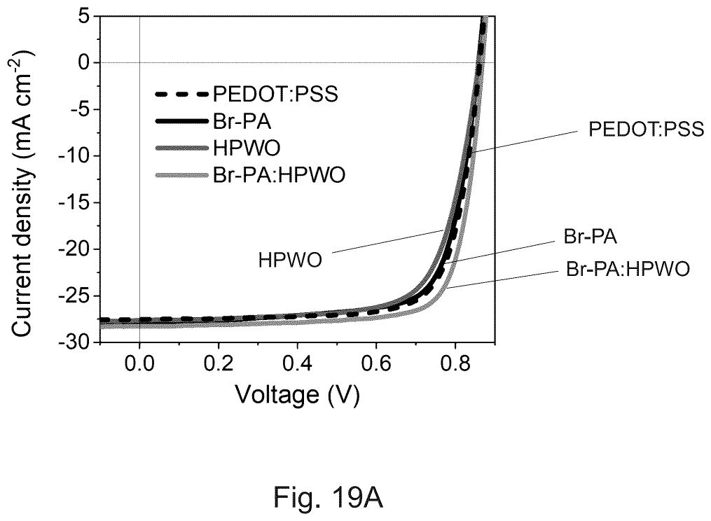

For the single-HPWO devices, the thickness of HPWO film was adjusted by screening the concentration in methanol ranging from 0.5 to 5 mg mL⁻¹. Among those, the film coated from 0.5 mg mL⁻¹ solution results in a champion PCE of 17.1% (FIG. 17), that is, a V_{OC} of 0.859 V, a short-circuit current density (J_{SC}) of 27.6 mA cm⁻², and an FF of 71.9%. The thicker HPWO leads to sharply decreased V_{OC} and FF (FIGS. 18A and 18B), possibly due to the deep-lying HOMO level of HPWO (−7.75 eV) that will block the hole extraction under thick-film condition (FIG. 5).

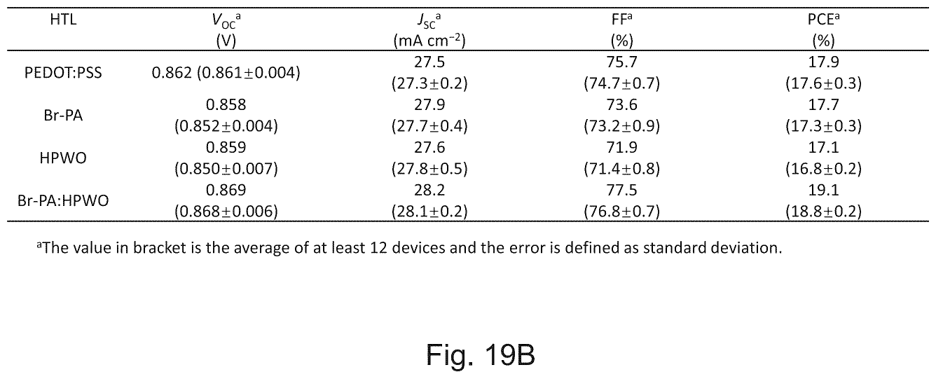

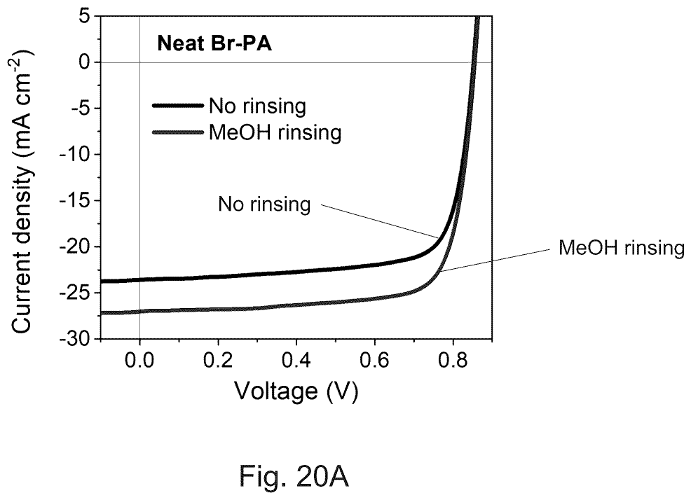

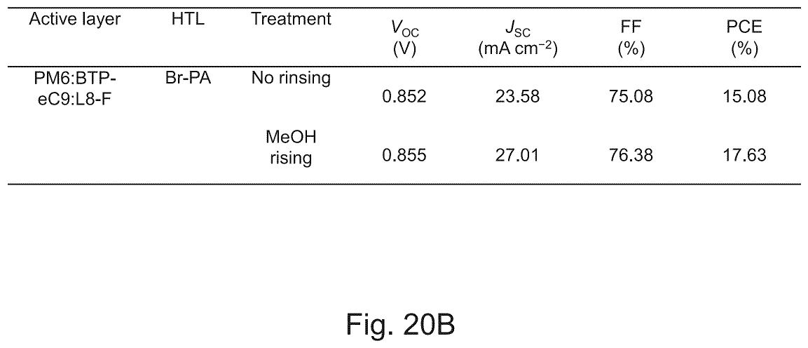

The processing of Br-PA was according to a standard procedure. Devices based on single-Br-PA (rinsed by isopropanol) show a higher PCE (17.7%) than that of HPWO-based devices (FIGS. 19A and 19B), mainly due to their higher J_{SC} (27.9 mA cm⁻²) and FF (73.6%). Note that the methanol rinsing of Br-PA leads to a similar PCE (17.6%) as that obtained from isopropanol rinsing, while the devices comprising as-cast SAM without solvent-rinsing deliver a much lower PCE of 15.1% (FIGS. 20A and 20B), confirming the removal of excess SAM molecules that are not chemisorbed by the substrate is importance for the OSC performance. Both Br-PA- and HPWO-devices are not as efficient as the PEDOT:PSS-based control devices that deliver an FF of 75.7% and a PCE of 17.9%, which could be attributed to the inferior interface coverage in devices comprising mono-layer or ultra-thin HTLs. However, the SDC-HTL that integrates Br-PA with HPWO (spin-coated from 0.5 mg mL⁻¹ methanol solution) leads to a significantly increased PCE of 19.1% in corresponding devices, owing to the improvement in all three parameters (V_{OC}=0.869 V, J_{SC}=28.2 mA cm⁻², and FF=77.5%).

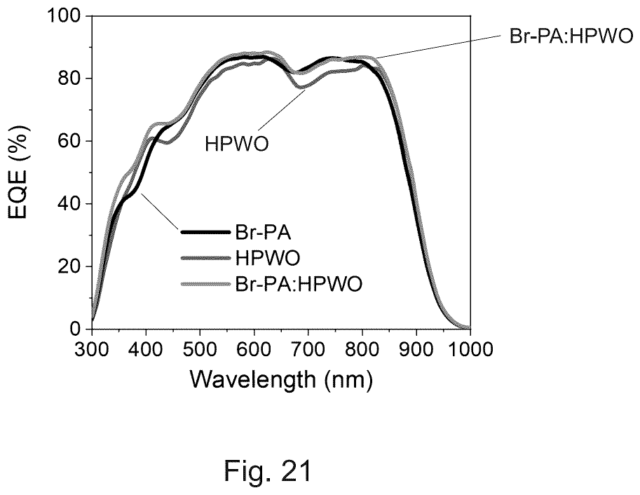

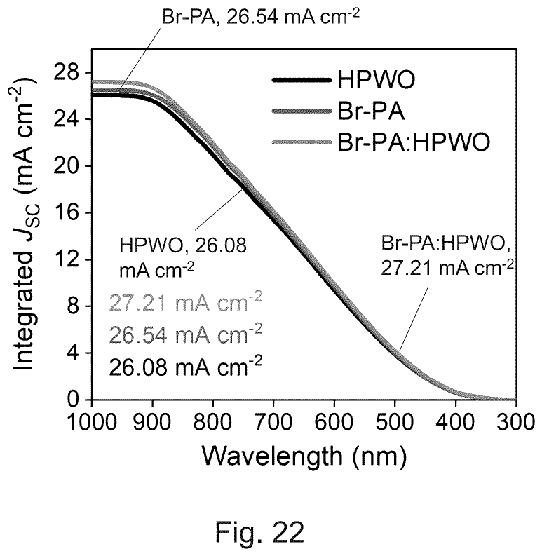

FIG. 21 shows slightly higher external quantum efficiency (EQE) of Br-PA:HPWO-devices than that of Br-PA-counterparts in the region of 600-900 nm, consistent with the slightly higher transmittance and smoother surface profile of the composite HTL. The HPWO-devices show lower EQE response than the other devices in almost the whole spectral region. This discrepancy from the higher transmittance of HPWO might be ascribed to the major vacancies formed on the film that affects the interfacial ohmic contact. The integrated current densities from EQE (FIG. 22) are within 4% mismatch compared with those obtained from current density-voltage (J-V) characteristics.

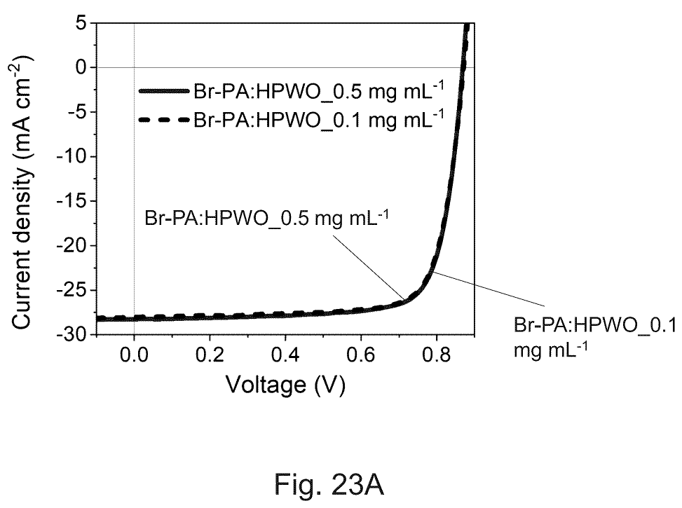

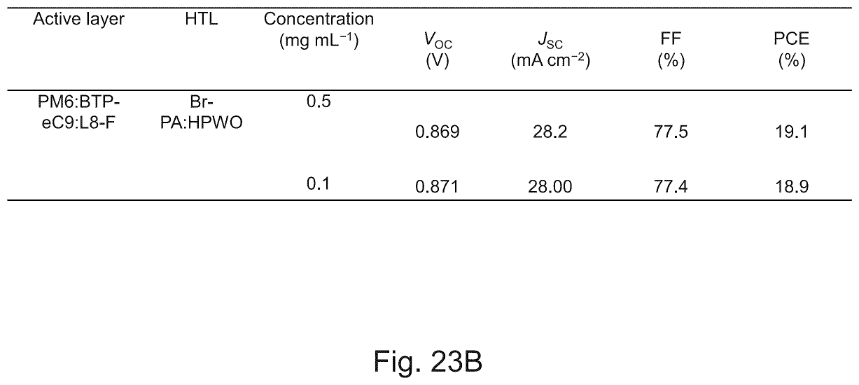

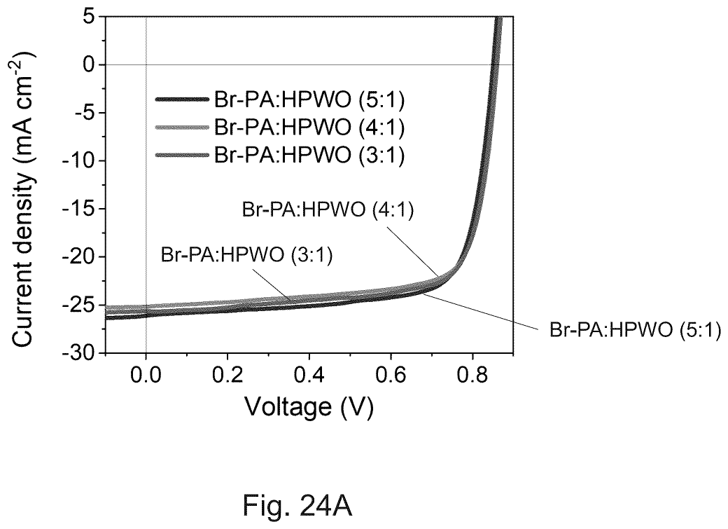

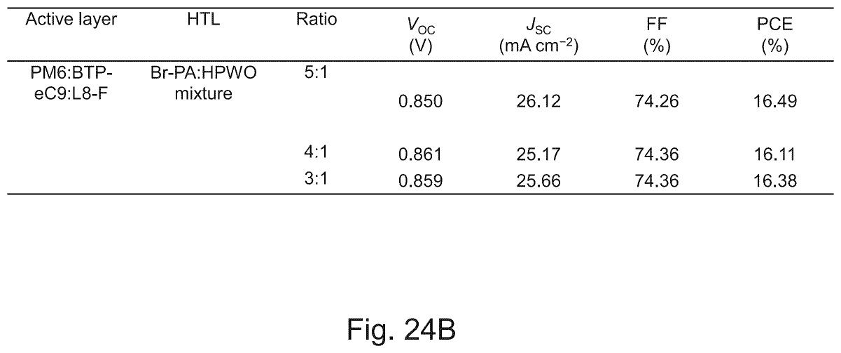

The SDC-HTL with HPWO coated from even lower concentration (0.1 mg mL⁻¹ in methanol) delivers a similar PCE of 18.9% (i.e., a V_{OC} of 0.871 V, a J_{SC} of 28.0 mA cm⁻², and an FF of 77.4%) in OSCs (FIGS. 23A and 23B), implying the changed HPWO concentration within the dilute scale has negligible influence on the Br-PA:HPWO ratio in the bottom layer of SDC. Note that the one-pot processing of Br-PA:HPWO blend film leads to low PCE in OSCs regardless of blending ratios (FIGS. 24A and 24B), which may be due to the presence of excess Br-PA molecules that are not chemisorbed (cannot be selectively removed by solvent-rinsing given that HPWO can also be washed away) and the uncertainty in the vertical pattern of the blend film. This suggests the one-pot mixing of Br-PA and HPWO is not an effective way to integrate HTLs, and the composition ratio of Br-PA:HPWO mixture is not a decisive factor of the device performance.

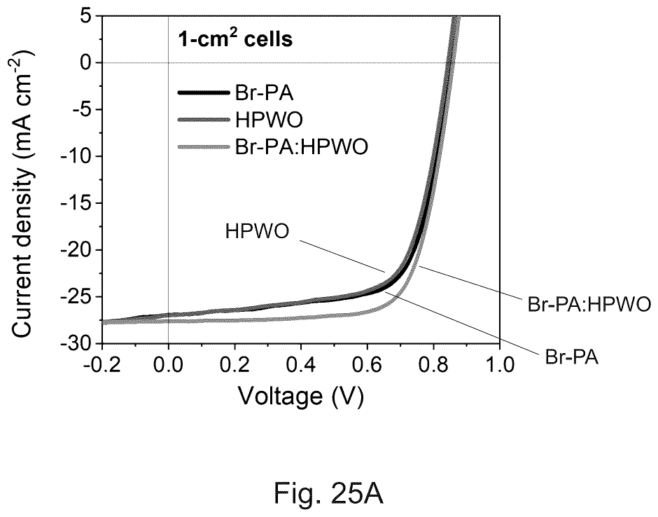

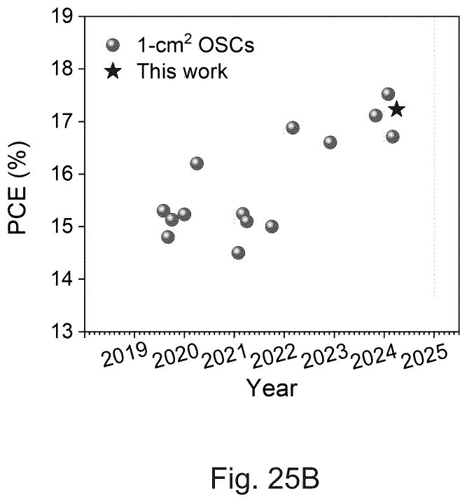

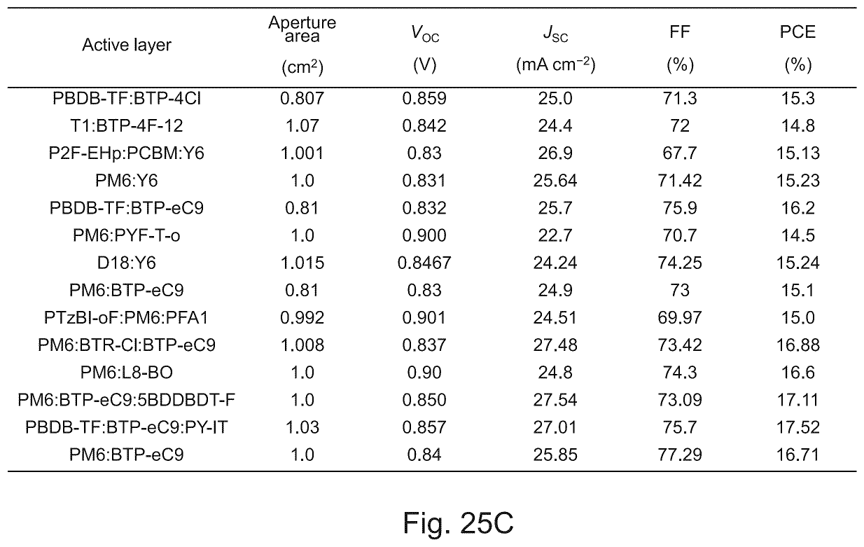

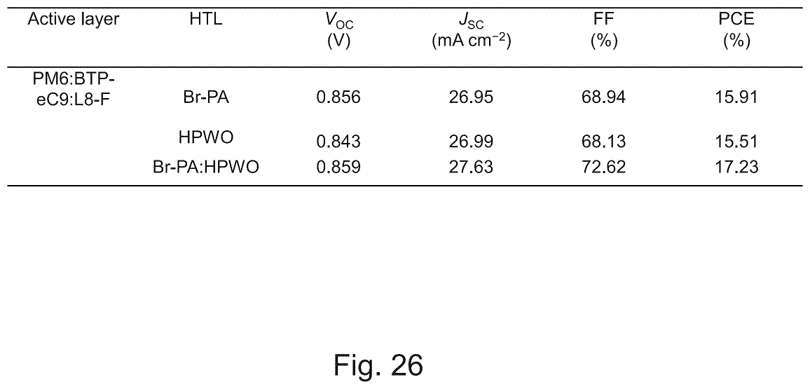

The industrial potential of Br-PA:HPWO SDC was evaluated in the centimeter-scale devices with cell width of ˜1 cm, in view of the fact that the optimal width of sub-cell for solar modules is generally in the centimeter scale. As depicted in FIG. 25A, a decent PCE of 17.23% was achieved under an aperture area of ˜1 cm², among the cutting-edge efficiencies of 1-cm² OSCs (FIGS. 25B and 25C). The inevitably reduced J_{SC} and FF along with the increased device width are generally derived from the inhomogeneities formed on the active layer and the attenuated charge extraction induced by substrate resistance. However, compared with that of small-area devices, the well reserved PCE in 1-cm² devices suggests the good compatibility of SAM:POM SDC with the up-scaling processing. By contrast, the 1-cm² devices based on single Br-PA and HPWO deliver a much inferior PCE of 15.91% and 15.51%, respectively (FIG. 26), implying that the SAM/POM methodology can also lead to significant enhancement of device performance in large-area devices, representing an important step towards industrially viable OSCs.

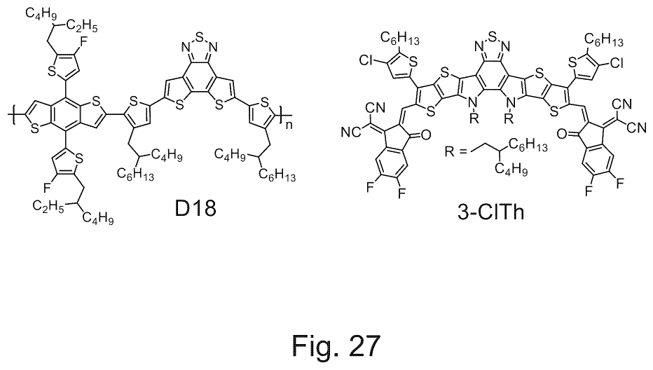

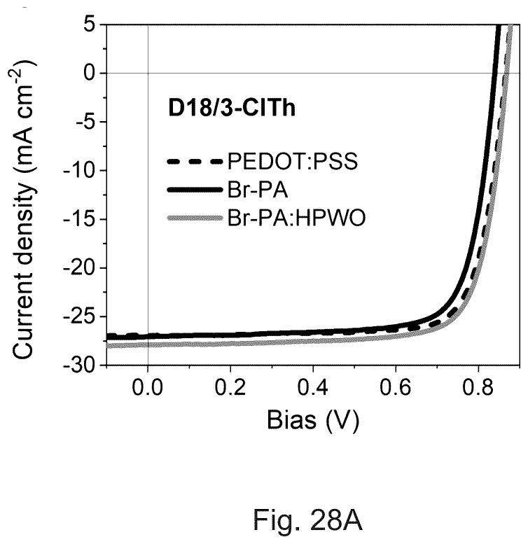

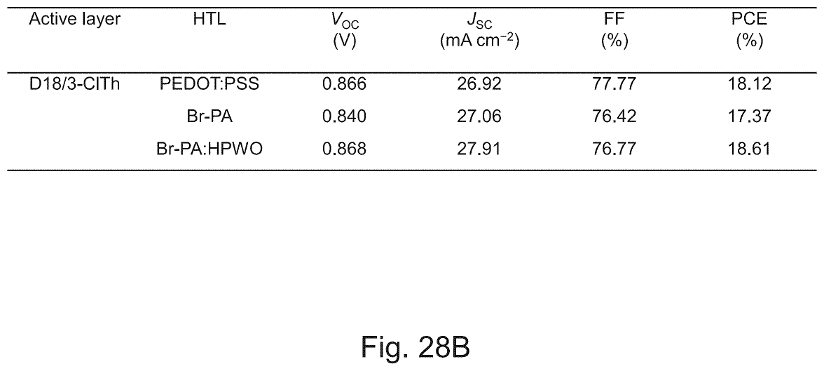

The validity of SDC-HTL was further verified in a pseudo-bilayer blending system based on a polymer donor, D18, and a non-fullerene acceptor, 3-CITh (FIG. 27). From the photovoltaic performance shown in FIGS. 28A and 28B, one can note a PCE of 18.61% achieved in Br-PA:HPWO-devices, higher than that of 18.12% and 17.37% for PEDOT:PSS- and Br-PA-devices, respectively. This is benefited from the superior V_{OC} (0.868 V) and J_{SC} (27.91 mA cm⁻²) in Br-PA:HPWO-devices, which should be a result of good interfacial contact and high visible-NIR transmittance of SDC-HTL. These results confirm the SAM:POM SDC could be a universal strategy for different material systems.

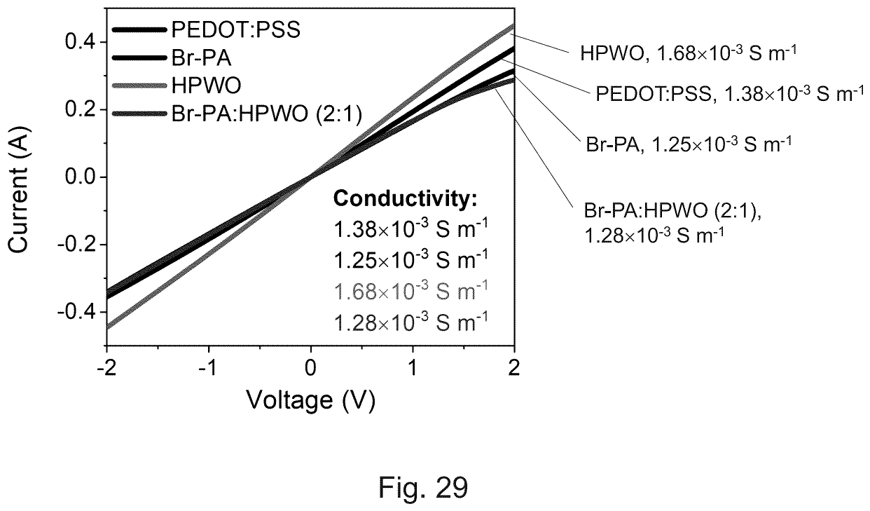

The electrical conductivity (σ) of different HTLs was measured using a sandwiched structure of ITO/HTL/Ag under dark condition. As the ultra-thin monolayer is not applicable for the conductivity measurement, the Br-PA was made into a bulk film with thickness of ˜30 nm. Accordingly, the Br-PA:HPWO mixture with weight ratio of 2:1 was used as the alternative of SDC-HTL. According to the I-V curves plotted in FIG. 29, the conductivity of PEDOT:PSS, Br-PA, HPWO, and Br-PA:HPWO (2:1) was calculated to be 1.38×10⁻³, 1.25×10⁻³, 1.68×10⁻³, and 1.28×10⁻³ S m⁻¹, respectively. Note the conductivity of HPWO is higher than that of PEDOT:PSS, similar to that observed in reports. Br-PA shows lower conductivity than that of PEDOT:PSS and HPWO, which though would not affect the hole extraction due to the tunneling dominates in such monolayer-HTL based devices. Br-PA:HPWO blend shows similar conductivity as that of neat Br-PA, suggesting the improved performance of Br-PA:HPWO-devices is not due to the changes in conductivity.

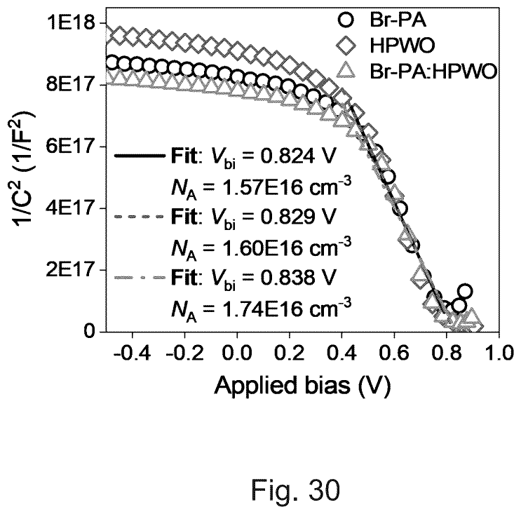

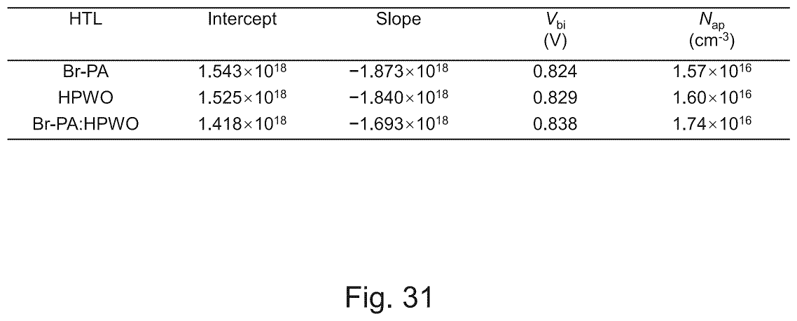

Capacitance-voltage (C-V) measurements were conducted to investigate the charge carrier concentration in PM6-devices comprising different HTLs. The Mott-Schottky characteristics derived from 1/C²-V relationship (FIG. 30) were plotted to determine the doping density (N_{A}) and built-in voltage (V_{bi}) within these devices. This is because of the fact that the charges generated in the depletion region is entirely due to the dopant species. By tuning the applied DC bias (V), the change in the width of depletion region will lead to the modulated capacitance, conforming to a formula, 1/C²=(2/qε₀εᵣN_{A}A²) (V_{bi}−V), where q is the elementary charge, εᵣ is the vacuum dielectric constant, εᵣ is the relative dielectric constant of the doped semiconductor, and A is the active area of the device. The parameters derived from the linear fitting were summarized in FIG. 31. The HPWO- and Br-PA:HPWO-devices show slightly higher N_{A} than that of Br-PA-devices, which should be due to the p-doping of polymer donor (PM6) by HPWO as proven above. Moreover, a higher V_{bi} compared with their counterparts bearing single Br-PA (0.824 V) is observed in HPWO-containing devices especially the composite-ones (0.838 V). This increased V_{bi} matches well with the increase in the measured V_{OC} of corresponding solar cells.

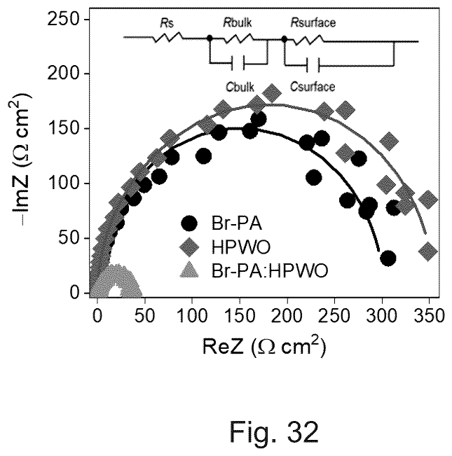

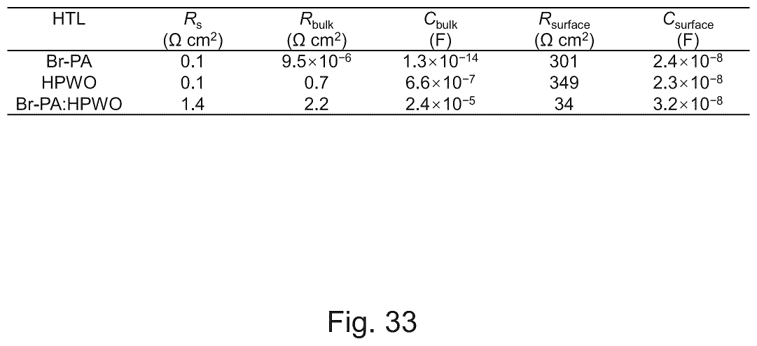

FIG. 32 shows the Nyquist plots derived from AC impedance spectra of PM6-devices comprising different HTLs measured in the dark. The data were fitted using an equivalent circuit model illustrated as inset in FIG. 32, where the two capacitors represent the depletion-(C_{surface}) and bulk-capacitance (C_{bulk)}, respectively. R_{surface} and R_{bulk} are resistance components forming a parallel circuit with C_{surface} and C_{bulk}, while Rₛ represents the series resistance. The fitted capacitance and resistance values are summarized in FIG. 33. The R_{surface} of SDC-HTL devices decreased sharply to 34Ω cm² from that of 301Ω cm² and 349Ω cm² for devices based on Br-PA and HPWO, respectively. This observation indicates an increased charge carrier density in the composite interface, which is possibly resulted from the combined efficient p-doping and less surface vacancies at the interface.

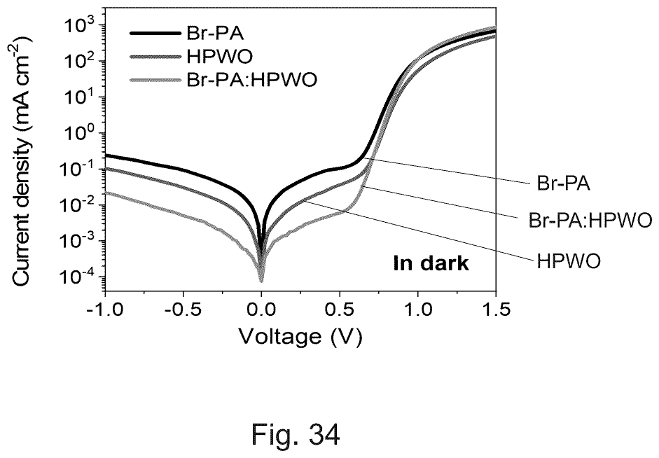

This was further confirmed by the dark J-V curves and photocurrent density-effective voltage (Jₚₕ-V_{eff}) plots. The series resistance (Rₛ) is determined to be 0.80, 0.96, and 0.57 (2 cm² for Br-PA-, HPWO-, and Br-PA:HPWO-devices, while the shunt resistance (Rₛₕ) is calculated as 6.34×10⁴, 2.77×10⁵, and 1.23×10⁶Ω cm², respectively (FIG. 34). The lowest Rₛ and highest Rₛₕ of Br-PA:HPWO-devices indicate the inclusion of SDC-HTL can reduce the ohmic loss in the devices.

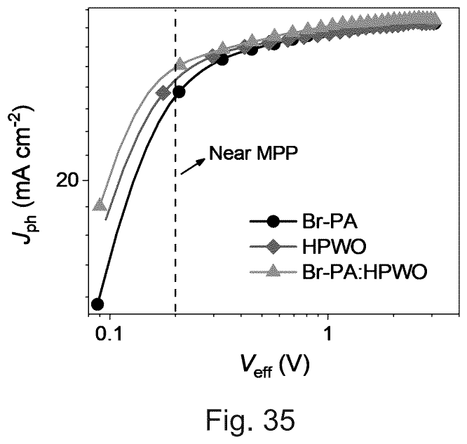

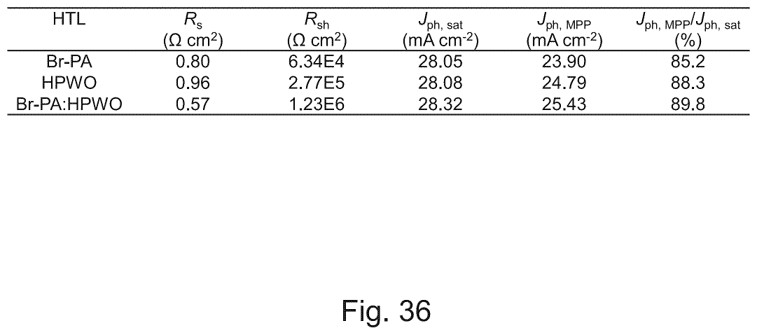

From the Jₚₕ-V_{eff} curves displayed in FIG. 35, the saturated Jₚₕ (Jₚₕ, sat) was determined at V_{eff}>3V, giving a value of 28.05, 28.08, and 28.32 mA cm⁻² for Br-PA-, HPWO-, and Br-PA:HPWO-devices, respectively (FIG. 36). The higher J_{ph,sat} of SDC-HTL devices suggests a larger exciton generation/dissociation probability in these devices. The charge extraction was evaluated in the low-V_{eff} region (V_{eff}=0.2 V) via determining the ratio of the Jₚₕ around MPP (J_{ph,MPP}) to J_{ph,sat}. The J_{ph, MPP}/J_{ph,sat} is calculated to be 85.2%, 88.3%, and 89.8% for Br-PA-, HPWO-, and Br-PA:HPWO-devices, respectively. Obviously, the SDC-HTL devices show higher charge collection probability than that of counterparts based on neat Br-PA or HPWO, confirming the better interfacial contact enabled by the SDC-HTL strategy. These results also validate the higher J_{SC} in solar cells comprising SDC-HTL.

### Example 5

### Long-Term Thermal and Photo Stability

To evaluate the long-term stability of solar cells comprising different HTLs, the unencapsulated PM6-based devices were aged under continuous heating at 65° C. in nitrogen atmosphere or tracked at the maximum power point (MPP) under continuous illumination at one sun. The thermal aging under 65° C. is according to the “ISOS-D-2” test protocol from the International Summits on Organic Photovoltaic Stability (ISOS). The aging temperature is considered to be higher than the maximum outdoor operating temperatures. The light source for MPP testing was provided by a white LED lamp with simulated AM 1.5G spectrum and tunable light intensity.

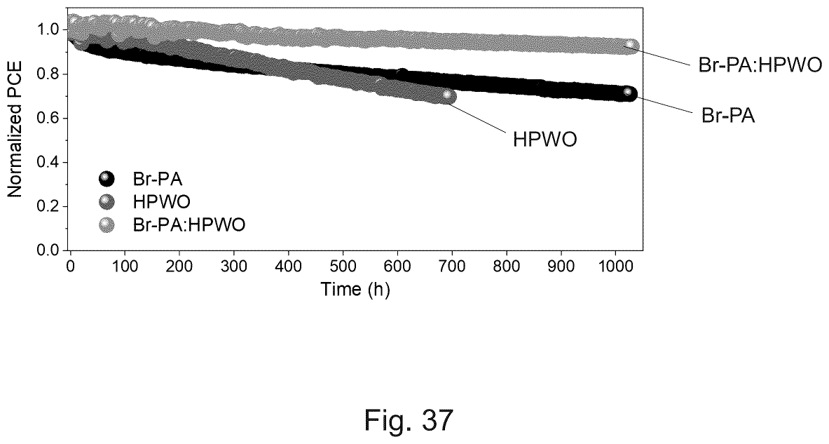

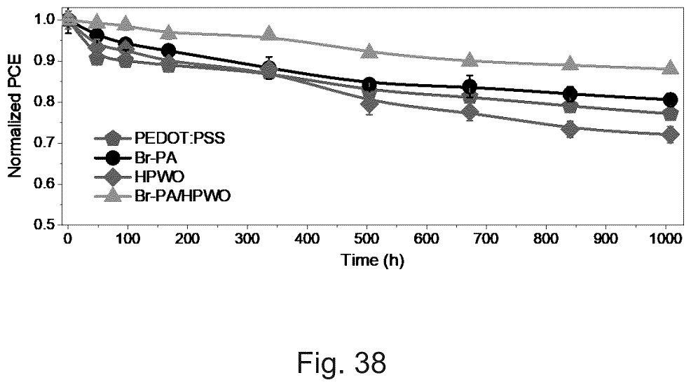

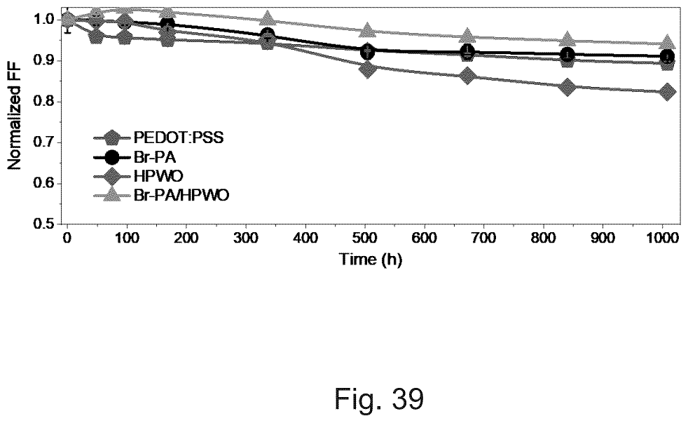

As illustrated in FIGS. 37 and 38, the devices based on Br-PA:HPWO SDC-HTL show burn-in free feature in both thermal and MPP aging conditions. However, a gradual degradation in PCE can be observed in extended period of thermal aging process, which is mainly due to the deterioration of FF (FIG. 39). However, compared with Br-PA:HPWO-devices showing only 6% loss of original FF after been aged at 65° C. for ˜1000 h, those of PEDOT:PSS- and Br-PA-devices are much higher (˜11% FF loss). The HPWO-devices are even worse, with only 82.4% of their original FF remained.

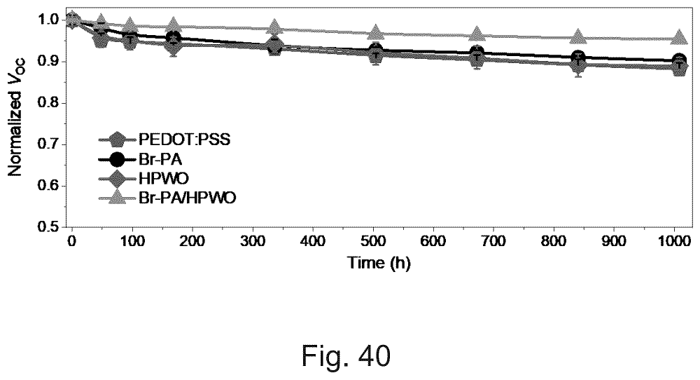

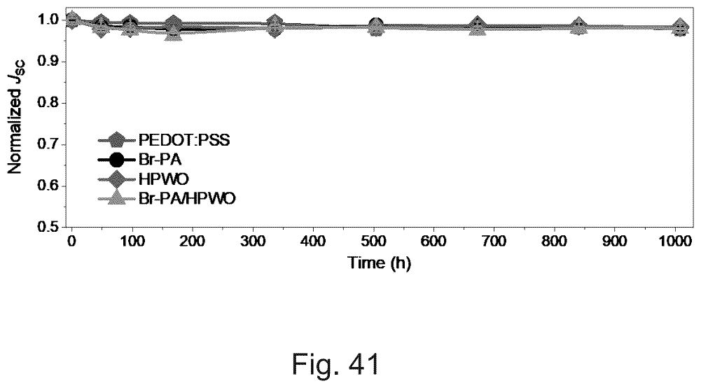

Another parameter that needs to be concerned is the V_{OC}. Br-PA:HPWO-devices deliver a robust V_{OC} with 95.5% of the original value remained, while those of PEDOT:PSS-, Br-PA-, and HPWO-devices decreased to 88-90% (FIG. 40).

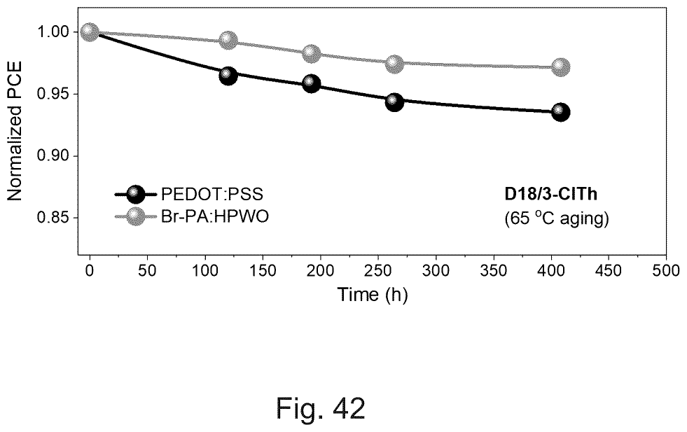

The stable FF and V_{OC} of Br-PA:HPWO-devices could be ascribed to the robustness of interfacial ohmic contact of SDC-HTL with active layer during thermal aging. Since the J_{SC} is stable for all devices (FIG. 41), the SDC-HTL devices with the most robust FF and V_{OC} show the best stability with the overall PCE remaining 88.0% compared with the initial value (FIG. 38). This is much better than those of counterparts based on single Br-PA and single HPWO with only 80.6% and 72.0% original PCE remained, respectively. D18-based devices also show superior thermal stability when employing Br-PA:HPWO SDC as HTL. Compared with PEDOT:PSS-devices that retain 93.5% of original PCE after aged at 65° C. for ˜400 h, a higher value of 97.2% is maintained in Br-PA:HPWO-devices and meanwhile showing inapparent burn-in loss within the initial 100 h (FIG. 42). The MPP tracking curves of PM6-devices show a similar decaying trend as those observed in thermal aging. Compared with Br-PA-devices showing a quickly degraded PCE in the initial 20 h, no obvious burn-in process can be discerned for HPWO- and Br-PA:HPWO-devices (FIG. 37). However, the PCE of HPWO-devices exhibits a sharp and continuous degradation after 200 h, which might be related with the vacancies and pin-holes observed in the HPWO layer. In contrast, the SDC-HTL devices show a slow degradation over the whole aging period, with 92.5% of the original efficiency remained after a long MPP tracking period of 1030 h.

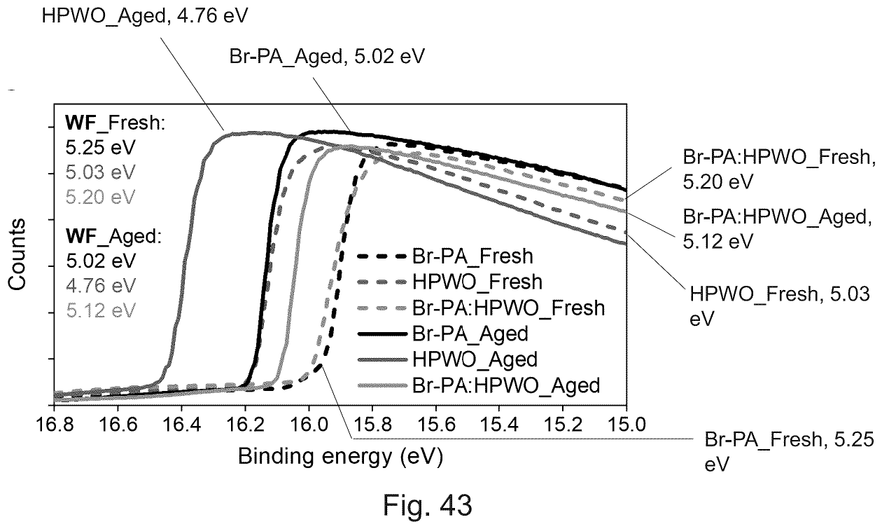

To elucidate the degradation of V_{OC} and FF in the devices during aging, UPS was used to track the changes in WF and HOMO levels, and AFM was employed to monitor the changes in surface profile. For a comparison to fresh HTLs, all HTLs on ITO were treated with accelerated thermal aging at 120° C. for 24 h in nitrogen atmosphere. From the high BE portion of UPS spectra (FIG. 43), one notes a sharp reduction in the WF of aged Br-PA (from 5.25 to 5.02 eV) and HPWO (from 5.03 to 4.76 eV), while that of aged Br-PA:HPWO decreases much more slowly (from 5.20 to 5.12 eV). This largely explains the much slower degradation of V_{OC} for Br-PA:HPWO-devices with respect to that of Br-PA- or HPWO-devices.

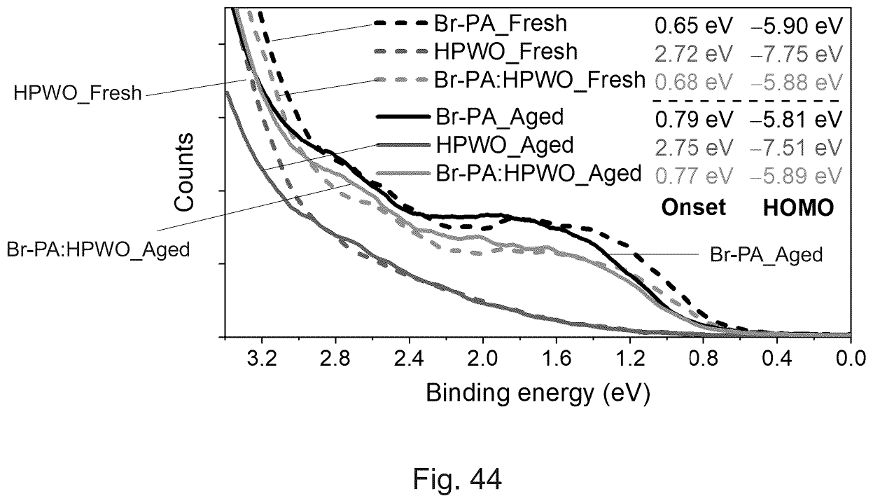

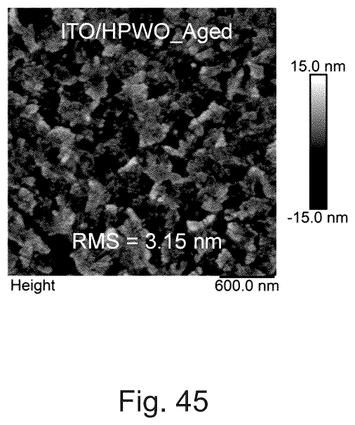

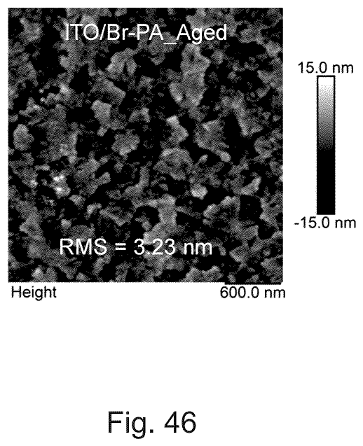

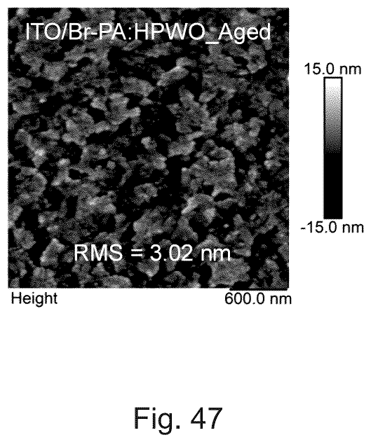

By further extracting the UPS onset in low BE region, Br-PA presents slightly up-shifted HOMO level from −5.90 to −5.81 eV after aging, whereas that of aged HPWO up-shifts greatly from −7.75 to −7.51 eV (FIG. 44). This implies the possible aggregation may happen in the HPWO film during aging. For the Br-PA:HPWO SDC, an almost identical HOMO level is observed (−5.88 vs.−5.89 eV) for fresh and aged film, indicating the SDC strategy could efficiently suppress the change of each component under stresses. To verify this, AFM was further measured for the aged HTLs to reveal the possible changes in surface profiles. Compared with the height image of fresh HPWO film (FIG. 6B), thermal aging leads to obviously enlarged feature size and increased RMS in the aged HPWO film (FIG. 45). In contrast, no discernable changes in the grain features can be seen for ITO/Br-PA (FIGS. 6A and 46) and ITO/Br-PA:HPWO (FIGS. 6C and 47), with the surface roughness remaining nearly unchanged or even decreased. This suggests the HPWO film tends to form aggregates in the aging process, while Br-PA and Br-PA:HPWO show stable morphology against thermal aging. The tendency of HPWO to form aggregates should be the origin that leads to the fastest degradation of HPWO-devices under both light and heat stresses.

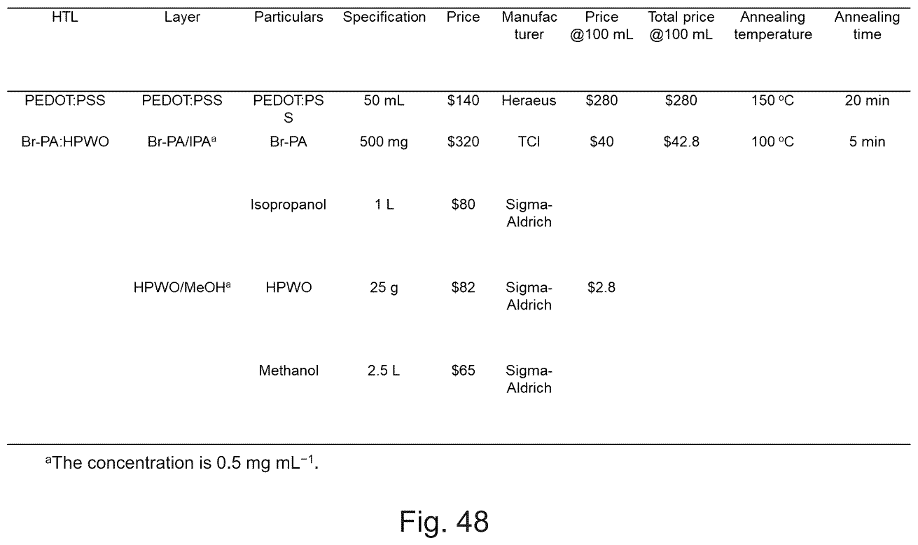

As proved above, in the SDC-HTL, the HPWO molecules mainly fill in the vacancies of SAM layer, while forming another discontinuous layer on top. In the aging process, the bottom SAM-dominate layer will retain immobilized by the HPWO, while the upper discontinuous HPWO may experience aggregation. Since a dense SAM:HPWO layer is formed at the bottom, the possible changes in the ultra-thin upper discontinuous HPWO should not obviously deteriorate the device performance. Therefore, the SDC-HTL devices show much better stability than that of either SAM or HPWO devices. These results confirm the superiority of integrating Br-PA with HPWO for modifying the interfacial properties and improving the long-term stability of OSCs. Combined with the lower cost and more facile processing of Br-PA:HPWO SDC with respect to those of PEDOT:PSS (FIG. 48), it is believed that the SAM:POM SDC-HTL in this work would become a great candidate as alternative of the traditional HTL, such as PEDOT:PSS.

The invention has been given by way of example only, and various other modifications of and/or alterations to the described embodiment may be made by persons skilled in the art without departing from the scope of the invention as specified in the appended claims.

The invention claimed is:

1. A composite material for an organic solar cell comprising a polyoxometalate (POM) cluster and a self-assembled monolayer (SAM) of a carbazole-based compound.

2. The composite material as claimed in claim 1, wherein the carbazole-based compound has a Formula of: 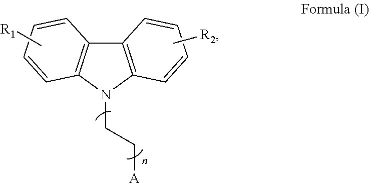
wherein:
R¹ and R² each represent a mono- or di-substitutions, and are each independently selected from the group consisting of hydrogen, halogen, alkyl, alkoxy, fused ring, non-fused ring, and a combination thereof;
n is a positive integer being 1-3; and
A is an anchoring group including an acid moiety.

3. The composite material as claimed in claim 2, wherein R₁ and R₂ are each independently selected from the group consisting of H, F, Cl, Br, I, C1-C6 alkyl, C1-C6 alkoxy, C6-C10 aryl, C5-C10 heteroaryl, and a combination thereof.

4. The composite material as claimed in claim 2, wherein A is selected from the group consisting of carboxyl group, sulfo group, mercapto group, and phosphono group.

5. The composite material as claimed in claim 2, wherein R₁ and R₂ are identical.

6. The composite material as claimed in claim 2, wherein R₁ and R₂ are different.

7. The composite material as claimed in claim 5, wherein the carbazole-based compound has a Formula selected from the group consisting of: 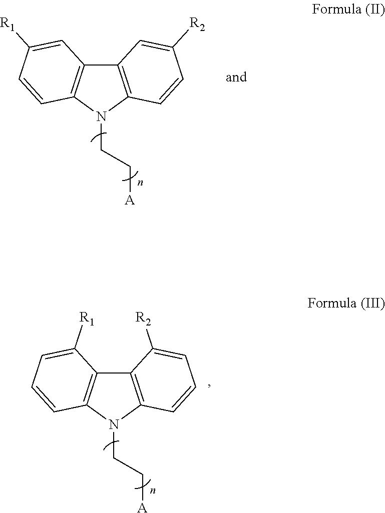
wherein:
R¹ and R² each represent a mono-substitution and are selected from the group consisting of H, F, Cl, Br, I, methyl, ethyl, methoxy, ethoxy, tert-butoxy, and phenyl;
n is 1-3; and
A is selected from the group consisting of carboxyl group, sulfo group, mercapto group, and phosphono group.

8. The composite material as claimed in claim 6, wherein the carbazole-based compound has a Formula selected from the group consisting of: 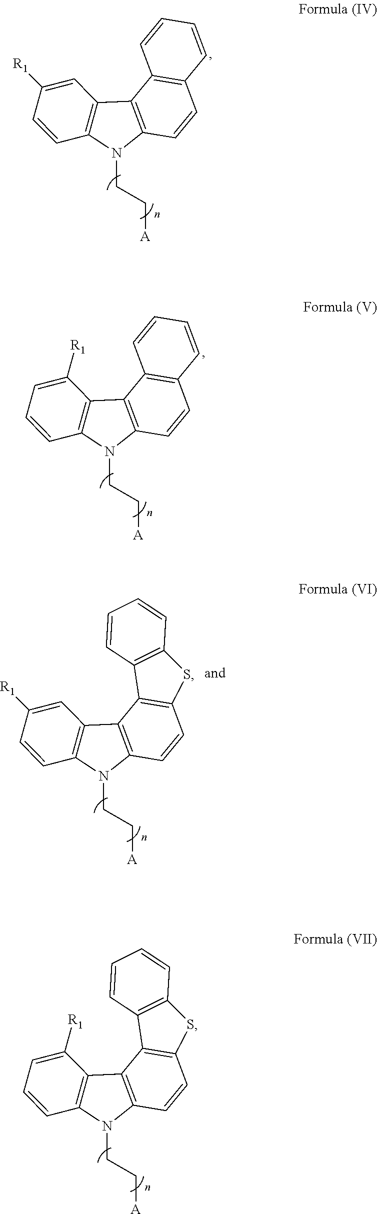
wherein:
R₁ represents a mono-substitution and is selected from the group consisting of H, F, Cl, Br, I, methyl, ethyl, methoxy, ethoxy, tert-butoxy, and phenyl;
n is 1-3; and
A is selected from the group consisting of carboxyl group, sulfo group, mercapto group and phosphono group.

9. The composite material as claimed in claim 7, wherein the carbazole-based compound has a Formula selected from the group consisting of:

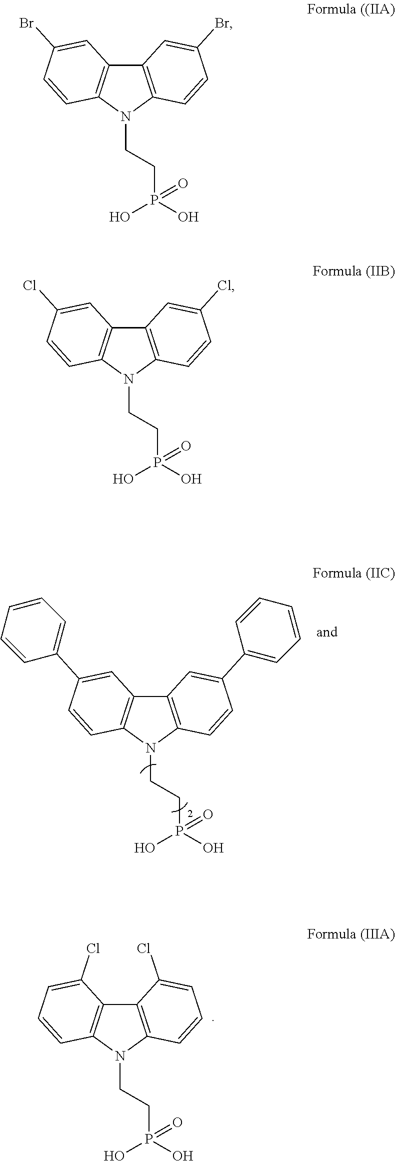

10. The composite material as claimed in claim 1, wherein the POM cluster comprises a Keggin structure.

11. The composite material as claimed in claim 1, wherein the POM cluster comprises a Dawson structure.

12. The composite material as claimed in claim 10, wherein the POM cluster has a formula of XₐYMₙM′₁₂₋ₙO₄₀, and wherein X is a cation selected from the group consisting of H⁺, NH₄⁺, NR₄⁺ with R being a C1-C4 linear or branched alkyl; a is 3 or 4; Y is selected from the group consisting of Si and P; M and M′ are selected from the group consisting of W and Mo; and n is 0-12.

13. The composite material as claimed in claim 12, wherein the POM cluster has a formula of H₃PW₁₂O₄₀.

14. The composite material as claimed in claim 11, wherein the POM cluster has a formula of X_{b}Y₂M_{n′}M′_{18-n′}O₆₂, and wherein X is a cation selected from the group consisting of H⁺, NH₄⁺, NR₄⁺ with R being a C1-C4 linear or branched alkyl; b is 6 or 8; Y is selected from the group consisting of Si and P; M and M′ are selected from the group consisting of W and Mo; and n′ is 0-18.

15. The composite material as claimed in claim 1, wherein the POM cluster is configured to form a discontinuous layer on the SAM.

16. The composite material as claimed in claim 15, wherein the POM cluster intercalates with the SAM by filling into nanovoids of the SAM.

17. The composite material as claimed in claim 1, wherein the SAM and the POM cluster have a concentration ratio of about 1:1 to about 1:40.

18. The composite material as claimed in claim 1 is a hole transporting layer material.

19. A method for preparing the composite material as claimed in claim 1, comprising the steps of:
a) depositing a SAM of a carbazole-based compound on a substrate to form a first substrate; and
b) depositing a POM cluster on the first substrate to form a discontinuous layer on the first substrate.

20. The method as claimed in claim 19, wherein step b) is carried out without pre-rinsing the first substrate.

21. The method as claimed in claim 19, wherein step b) is carried out without post-annealing.

22. The method as claimed in claim 19, wherein steps a) and b) are each carried out by way of spin-coating.

23. An organic solar cell comprising a hole transporting layer including the composite material as claimed in claim 1.

24. The organic solar cell as claimed in claim 23 further comprising:
an anode and a cathode, between which the hole transporting layer is disposed;
an electron transporting layer disposed between the anode and the cathode; and
a photoactive layer disposed between the hole transporting layer and the electron transporting layer.

25. The organic solar cell as claimed in claim 24, wherein the photoactive layer is in direct contact with the hole transporting layer and the electron transporting layer.

26. The organic solar cell as claimed in 24, wherein the photoactive layer is configured as any one of the following structures: a bulk heterojunction, a quasi-planar heterojunction and a pseudo-bilayer.
